(19) United States
(12) Patent Application Publication
(10) Pub. No.: US 2024/0315007 A1
(43) Pub. Date: Sep. 19, 2024

(54) SEMICONDUCTOR DEVICE

(71) Applicant: Kioxia Corporation, Tokyo (JP)

(72) Inventors: Kotaro NODA, Yokkaichi Mie (JP); Takahiro FUJII, Nagoya Aichi (JP); Takanori AKITA, Yokkaichi Mie (JP); Mutsumi OKAJIMA, Yokkaichi Mie (JP)

(73) Assignee: Kioxia Corporation, Tokyo (JP)

(21) Appl. No.: 18/592,970

(22) Filed: Mar. 1, 2024

(30) Foreign Application Priority Data
Mar. 13, 2023 (JP) 2023-038202

(51) Int. Cl. H10B 12/00

(52) U.S. Cl. CPC H10B 12/33; H10B 12/05

(57) ABSTRACT

A semiconductor device includes a first oxide semiconductor layer extending in a first direction, a first wiring extending in a second direction that intersects the first direction and surrounding the first oxide semiconductor layer, a first insulating film provided between the first wiring and the first oxide semiconductor layer, a first conductor provided on the first oxide semiconductor layer, a second wiring provided on the first conductor and extending in a third direction that intersects each of the first direction and the second direction, a first insulating layer in contact with a side surface of the second wiring, and a second insulating layer provided on the first insulating layer and having oxygen permeability lower than oxygen permeability of the first insulating layer.

### CROSS-REFERENCE TO RELATED APPLICATION (S)

This application is based upon and claims the benefit of priority from Japanese Patent Application No. 2023-038202, filed Mar. 13, 2023, the entire contents of which are incorporated herein by reference.

### FIELD

Embodiments described herein relate generally to a semiconductor device.

### BACKGROUND

A semiconductor storage device having a bit line, a word line, and a memory cell (transistor and capacitor) connected to the bit line and the word line is used. Data can be written into and read from the memory cell by selecting the bit line and the word line and applying a voltage.

### DESCRIPTION OF THE DRAWINGS

FIG. 1 is a circuit diagram showing a circuit configuration example of a memory cell array.

FIG. 2 is a plan schematic view showing a first structural example of the memory cell array.

FIG. 3 is a schematic cross-sectional view showing the first structural example of the memory cell array.

FIG. 4 is a schematic cross-sectional view showing the first structural example of the memory cell array.

FIG. 5 is a schematic cross-sectional view showing a manufacturing method example of the first structural example.

FIG. 6 is a schematic cross-sectional view showing the manufacturing method example of the first structural example.

FIG. 7 is a schematic cross-sectional view showing the manufacturing method example of the first structural example.

FIG. 8 is a schematic cross-sectional view showing the manufacturing method example of the first structural example.

FIG. 9 is a schematic cross-sectional view showing the manufacturing method example of the first structural example.

FIG. 10 is a schematic cross-sectional view showing the manufacturing method example of the first structural example.

FIG. 11 is a schematic cross-sectional view showing the manufacturing method example of the first structural example.

FIG. 12 is a schematic cross-sectional view showing the manufacturing method example of the first structural example.

FIG. 13 is a schematic cross-sectional view showing the manufacturing method example of the first structural example.

FIG. 14 is a schematic cross-sectional view showing the manufacturing method example of the first structural example.

FIG. 15 is a schematic cross-sectional view showing the manufacturing method example of the first structural example.

FIG. 16 is a schematic cross-sectional view showing the manufacturing method example of the first structural example.

FIG. 17 is a schematic cross-sectional view showing a first modification example of the first structural example.

FIG. 18 is a schematic cross-sectional view showing a second modification example of the first structural example.

FIG. 19 is a schematic cross-sectional view showing a third modification example of the first structural example.

FIG. 20 is a schematic cross-sectional view showing a fourth modification example of the first structural example.

FIG. 21 is a schematic cross-sectional view showing a fifth modification example of the first structural example.

FIG. 22 is a schematic cross-sectional view showing a sixth modification example of the first structural example.

FIG. 23 is a schematic cross-sectional view showing a seventh modification example of the first structural example.

FIG. 24 is a schematic cross-sectional view showing an eighth modification example of the first structural example.

FIG. 25 is a schematic cross-sectional view showing a ninth modification example of the first structural example.

FIG. 26 is a plan schematic view showing a manufacturing method example of a second structural example of the memory cell array.

FIG. 27 is a plan schematic view showing the manufacturing method example of the second structural example of the memory cell array.

FIG. 28 is a plan schematic view showing the manufacturing method example of the second structural example of the memory cell array.

FIG. 29 is a plan schematic view showing the manufacturing method example of the second structural example of the memory cell array.

FIG. 30 is a plan schematic view showing the manufacturing method example of the second structural example of the memory cell array.

FIG. 31 is a schematic cross-sectional view showing a modification example of the second structural example.

FIG. 32 is a plan schematic view showing a third structural example of the memory cell array.

FIG. 33 is a schematic cross-sectional view showing the third structural example of the memory cell array.

FIG. 34 is a schematic cross-sectional view showing a manufacturing method example of the third structural example.

FIG. 35 is a schematic cross-sectional view showing the manufacturing method example of the third structural example.

FIG. 36 is a schematic cross-sectional view showing the manufacturing method example of the third structural example.

FIG. 37 is a schematic cross-sectional view showing the manufacturing method example of the third structural example.

FIG. 38 is a schematic cross-sectional view showing a first modification example of the third structural example.

FIG. 39 is a schematic cross-sectional view showing a manufacturing method example of the first modification example of the third structural example.

FIG. 40 is a schematic cross-sectional view showing the manufacturing method example of the first modification example of the third structural example.

FIG. 41 is a schematic cross-sectional view showing a second modification example of the third structural example.

FIG. 42 is a schematic cross-sectional view showing a manufacturing method example of the second modification example of the third structural example.

FIG. 43 is a schematic cross-sectional view showing the manufacturing method example of the second modification example of the third structural example.

FIG. 44 is a schematic cross-sectional view showing the manufacturing method example of the second modification example of the third structural example.

FIG. 45 is a schematic cross-sectional view showing the manufacturing method example of the second modification example of the third structural example.

FIG. 46 is a schematic cross-sectional view showing the manufacturing method example of the second modification example of the third structural example.

FIG. 47 is a schematic cross-sectional view showing the manufacturing method example of the second modification example of the third structural example.

FIG. 48 is a schematic cross-sectional view showing a third modification example of the third structural example.

FIG. 49 is a schematic cross-sectional view showing a manufacturing method example of the third modification example of the third structural example.

FIG. 50 is a schematic cross-sectional view showing the manufacturing method example of the third modification example of the third structural example.

FIG. 51 is a schematic cross-sectional view showing the manufacturing method example of the third modification example of the third structural example.

FIG. 52 is a schematic cross-sectional view showing the manufacturing method example of the third modification example of the third structural example.

FIG. 53 is a schematic cross-sectional view showing the manufacturing method example of the third modification example of the third structural example.

FIG. 54 is a schematic cross-sectional view showing the manufacturing method example of the third modification example of the third structural example.

FIG. 55 is a schematic cross-sectional view showing a fourth modification example of the third structural example.

FIG. 56 is a schematic cross-sectional view showing a fifth modification example of the third structural example.

FIG. 57 is a schematic cross-sectional view showing a sixth modification example of the third structural example.

FIG. 58 is a schematic cross-sectional view showing a manufacturing method example of the sixth modification example of the third structural example.

FIG. 59 is a schematic cross-sectional view showing the manufacturing method example of the sixth modification example of the third structural example.

FIG. 60 is a schematic cross-sectional view showing the manufacturing method example of the sixth modification example of the third structural example.

FIG. 61 is a schematic cross-sectional view showing the manufacturing method example of the sixth modification example of the third structural example.

FIG. 62 is a schematic cross-sectional view showing the manufacturing method example of the sixth modification example of the third structural example.

FIG. 63 is a schematic cross-sectional view showing the manufacturing method example of the sixth modification example of the third structural example.

FIG. 64 is a schematic cross-sectional view showing a seventh modification example of the third structural example.

FIG. 65 is a schematic cross-sectional view showing a manufacturing method example of the seventh modification example of the third structural example.

FIG. 66 is a schematic cross-sectional view showing the manufacturing method example of the seventh modification example of the third structural example.

FIG. 67 is a schematic cross-sectional view showing the manufacturing method example of the seventh modification example of the third structural example.

FIG. 68 is a schematic cross-sectional view showing an eighth modification example of the third structural example.

FIG. 69 is a schematic cross-sectional view showing a ninth modification example of the third structural example.

FIG. 70 is a schematic cross-sectional view showing a manufacturing method example of the ninth modification example of the third structural example.

FIG. 71 is a schematic cross-sectional view showing the manufacturing method example of the ninth modification example of the third structural example.

FIG. 72 is a schematic cross-sectional view showing the manufacturing method example of the ninth modification example of the third structural example.

FIG. 73 is a schematic cross-sectional view showing the manufacturing method example of the ninth modification example of the third structural example.

FIG. 74 is a schematic cross-sectional view showing a tenth modification example of the third structural example.

FIG. 75 is a schematic cross-sectional view showing an eleventh modification example of the third structural example.

### DETAILED DESCRIPTION

Embodiments provide a semiconductor device reducing a decrease in reliability of a semiconductor device.

In general, according to one embodiment, the semiconductor device includes a first oxide semiconductor layer extending in a first direction, a first wiring extending in a second direction that intersects the first direction and surrounding the first oxide semiconductor layer, a first insulating film provided between the first wiring and the first oxide semiconductor layer, a first conductor provided on the first oxide semiconductor layer, a second wiring provided on the first conductor and extending in a third direction that intersects each of the first direction and the second direction, a first insulating layer in contact with a side surface of the second wiring, and a second insulating layer provided on the first insulating layer and having oxygen permeability lower than oxygen permeability of the first insulating layer.

Hereinafter, embodiments will be described with reference to the drawings. The relationship between the thickness and the plane dimensions of each element shown in the drawings, the ratio of the thicknesses of each element, and the like may differ from the actual relationship, ratio, and the like. The up-down direction may be different from the up-down direction according to the acceleration of gravity. Further, in the embodiments, substantially the same elements will be given the same reference numerals, and the description thereof will be omitted as appropriate.

In the present specification, the term “connection” includes not only a physical connection but also an electrical connection, and includes not only a direct connection but also an indirect connection, unless otherwise specified.

The semiconductor device of the embodiment is a dynamic random access memory (DRAM) having a memory cell array.

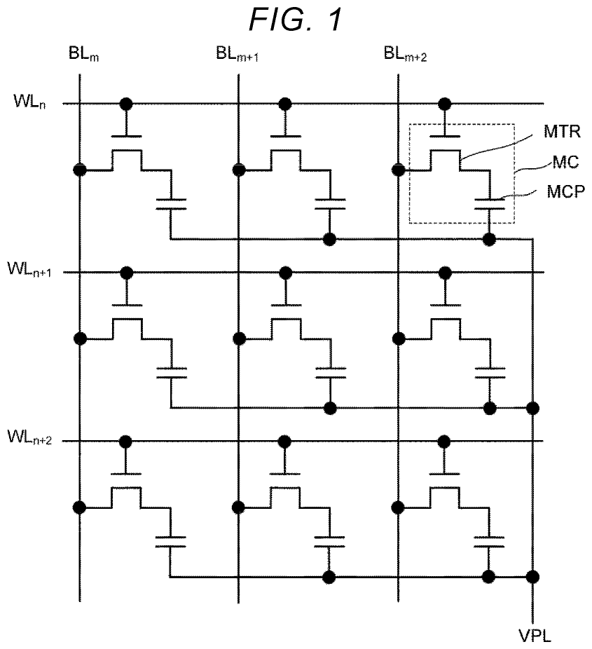

FIG. 1 is a circuit diagram showing a circuit configuration example of a memory cell array. FIG. 1 shows a plurality of memory cells MC, a plurality of word lines WL (word lines WLₙ, WLₙ₊₁, and WLₙ₊₂, n is an integer), a plurality of bit lines BL (bit lines BLₘ, BLₘ₊₁, and BLₘ₊₂, m is an integer), and a power supply line VPL.

The plurality of memory cells MC are arranged in a matrix direction to form a memory cell array. Each of memory cells MC includes a memory transistor MTR which is a field effect transistor (FET) and a memory capacitor MCP.

The field effect transistor has a gate, a source, and a drain. The field effect transistor may further have a back gate. Since the source and the drain are interchanged with each other depending on the structure or the operating conditions of the transistor, it is difficult to limit which of the source and the drain is the source or the drain. Therefore, unless otherwise specified, one terminal randomly selected from either the source or the drain is denoted as one of the source or the drain, and the other terminal is denoted as the other of the source or the drain.

The gate of the memory transistor MTR is connected to the corresponding word line WL, and one of the source or the drain is connected to the corresponding bit line BL. The word line WL is connected to, for example, a row decoder. The bit line BL is connected to, for example, a sense amplifier. The first electrode of the memory capacitor MCP is connected to the other of the source or the drain of the memory transistor MTR, and the second electrode is connected to the power supply line VPL that supplies a specific potential. The power supply line VPL is connected to, for example, a power supply circuit. The memory cell MC can store charges from the bit line BL in the memory capacitor MCP by switching of the memory transistor MTR by the word line WL and can store data. The number of the plurality of memory cells MC is not limited to the number shown in FIG. 1.

### First Structural Example of Memory Cell Array

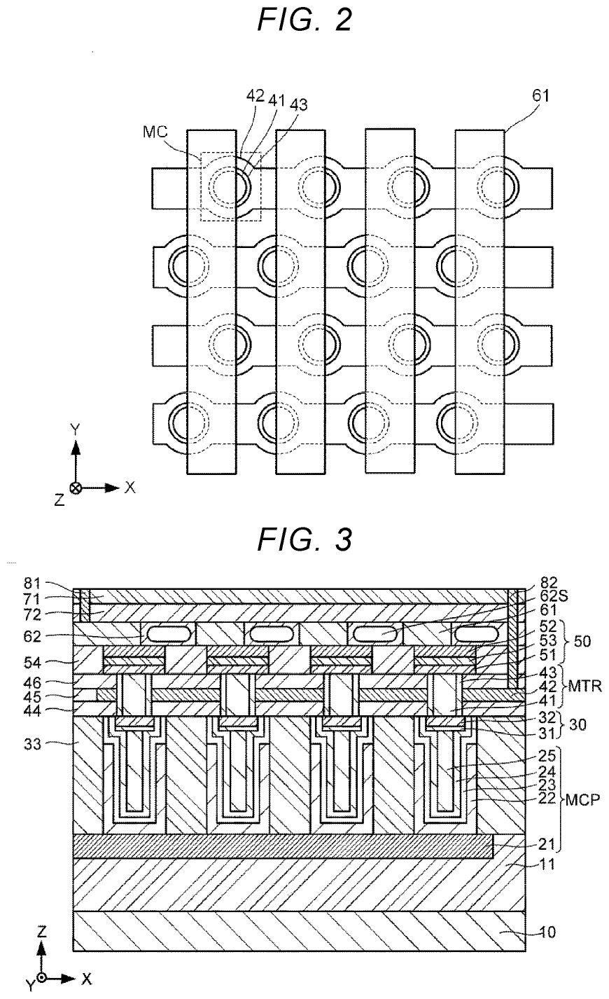

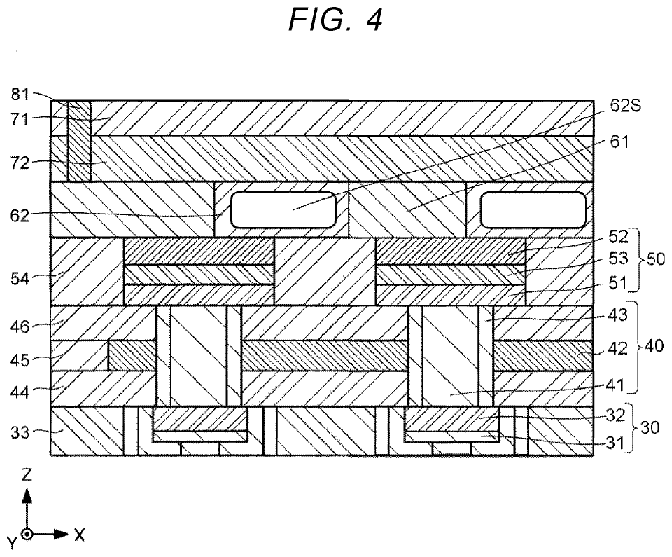

FIG. 2 is a plan schematic view showing a first structural example of the memory cell array of the embodiment. FIG. 3 is a schematic cross-sectional view showing a first structural example of the memory cell array of the embodiment. FIG. 4 is a schematic cross-sectional view showing a first structural example of the memory cell array of the embodiment. FIGS. 2 to 4 show an X-axis, a Y-axis, and a Z-axis. The X-axis, the Y-axis, and the Z-axis are orthogonal to each other. FIG. 2 shows a part of the X-Y plane. FIG. 3 shows a part of the X-Z cross section. FIG. 4 shows a part of FIG. 3.

The memory cell array includes a conductor 21, a conductive layer 22, an insulator 23, a conductor 24, an electric conductor 25, a conductive layer 31, a conductive oxide layer 32, an insulating layer 33, an oxide semiconductor layer 41, a conductive layer 42, an insulating film 43, an insulating layer 44, an insulating layer 45, an insulating layer 46, a conductive oxide layer 51, a conductive layer 52, a conductive layer 53, an insulating layer 54, a conductive layer 61, an insulating layer 62, an insulating layer 71, an insulating layer 72, a conductor 81, and a conductor 82. FIG. 2 shows the oxide semiconductor layer 41, the conductive layer 42, the insulating film 43, and the conductive layer 61, and other elements are not shown for convenience.

The memory transistor MTR and the memory capacitor MCP are provided above the insulating layer 11 on the semiconductor substrate 10. Peripheral circuits such as a row decoder, a sense amplifier, or a power supply circuit are formed on the semiconductor substrate 10. The peripheral circuit has, for example, a field effect transistor such as a P-channel type field effect transistor (Pch-FET) or an N-channel type field effect transistor (Nch-FET). The field effect transistor can be formed using a semiconductor substrate 10 such as a single crystal silicon substrate, and the Pch-FET and the Nch-FET have a channel region, a source region, and a drain region in the semiconductor substrate 10. The semiconductor substrate 10 may have a P-type conductive type. The insulating layer 11 is provided on the semiconductor substrate 10 and contains, for example, silicon (Si) and oxygen (O) or nitrogen (N). The insulating layer 11 may be a stacked film.

The conductor 21, the conductive layer 22, the insulator 23, the conductor 24, and the electric conductor 25 form the memory capacitor MCP. The memory capacitor MCP is a three-dimensional capacitor such as a so-called pillar-type capacitor or a cylinder-type capacitor.

The conductor 21 is provided above the semiconductor substrate 10 with the insulating layer 11 sandwiched therebetween. The conductor 21 extends to overlap the plurality of electric conductors 25 when viewed in the Z-axis direction. The conductor 21 is also referred to as a plate electrode. The conductive layer 22 is provided on a part of the conductor 21. The conductor 21 and the conductive layer 22 form a second electrode of the memory capacitor MCP. The insulator 23 is provided between the conductive layer 22 and the conductor 21, and between the conductor 24 and the electric conductor 25, and forms a dielectric of the memory capacitor MCP. The conductor 24 and the electric conductor 25 are provided above the conductor 21 with the insulator 23 sandwiched therebetween, extend in the Z-axis direction, and form a first electrode of the memory capacitor MCP. The electric conductor 25 is surrounded by the conductor 24.

The conductor 21, the conductive layer 22, and the conductor 24 include, for example, a material such as tungsten or titanium nitride. The insulator 23 includes, for example, a material such as hafnium oxide, zirconium oxide, or aluminum oxide. The electric conductor 25 includes, for example, a material such as tungsten, titanium nitride, or amorphous silicon.

The conductive layer 31 is provided on the electric conductor 25 and is electrically connected to the electric conductor 25. The conductive layer 31 includes, for example, copper. The conductive layer 31 does not necessarily have to be formed.

The conductive oxide layer 32 is provided on the conductive layer 31. The conductive oxide layer 32 contains, for example, a metal oxide such as indium-tin-oxide (ITO).

The conductive layer 31 and the conductive oxide layer 32 form the conductor 30. A plurality of the conductors 30 are provided with respect to the plurality of the electric conductors 25.

The insulating layer 33 is provided between the plurality of conductors 30. The insulating layer 33 contains, for example, silicon and oxygen or nitrogen.

The oxide semiconductor layer 41, the conductive layer 42, and the insulating film 43 form a field effect transistor 40 (memory transistor MTR). The field effect transistor 40 is, for example, an N-channel type field effect transistor. The field effect transistor 40 is provided above the memory capacitor MCP. A plurality of field effect transistors 40 are provided corresponding to the plurality of memory capacitors MCP.

The oxide semiconductor layer 41 is, for example, a columnar body extending in the Z-axis direction. The oxide semiconductor layer 41 penetrates the conductive layer 42 in the Z-axis direction. The oxide semiconductor layer 41 forms a channel of the field effect transistor 40. The oxide semiconductor layer 41 contains, for example, indium (In). The oxide semiconductor layer 41 includes, for example, indium oxide and gallium oxide, indium oxide and zinc oxide, or indium oxide and tin oxide. As an example, an oxide including indium, gallium, and zinc (indium-gallium-zinc-oxide), so-called InGaZnO (IGZO) is contained. The oxide semiconductor layer 41 may have an amorphous structure or may have a crystal structure by heat treatment.

One end of the oxide semiconductor layer 41 in the Z-axis direction is connected to the conductive layer 31 via the conductive oxide layer 32 and functions as the other of the source or the drain of the memory transistor MTR. The conductive oxide layer 32 is provided between the electric conductor 25 of the memory capacitor MCP and the oxide semiconductor layer 41 of the field effect transistor 40, and functions as the other of the source electrode or the drain electrode of the memory transistor MTR. The conductive oxide layer 32 contains a metal oxide in the same manner as that in the oxide semiconductor layer 41 of the field effect transistor 40, and thus the connection resistance between the memory transistor MTR and the memory capacitor MCP can be reduced.

The conductive layer 42 includes a portion facing the oxide semiconductor layer 41 the insulating film 43 sandwiched in the X-Y plane. The conductive layer 42 surrounds the oxide semiconductor layer 41 and the insulating film 43 in the X-Y plane. The conductive layer 42 forms a gate electrode of the memory transistor MTR and forms a word line WL as wiring. The conductive layer 42 includes, for example, a metal, a metal compound, or a semiconductor. The conductive layer 42 includes, for example, at least one material selected from the group consisting of tungsten (W), titanium (Ti), titanium nitride (TiN), molybdenum (Mo), cobalt (Co), and ruthenium (Ru).

In FIG. 2, the conductive layer 42 has a region that does not overlap with the field effect transistor 40 in the Y-axis direction, which has a width narrower than that of a region that overlaps with the field effect transistor 40 when viewed in the Y-axis direction. However, the present disclosure is not limited thereto, and a width of the conductive layer 42 in the Y-axis direction may be a constant value.

The plurality of conductive layers 42 extend in the X-axis direction and are parallel with each other, as shown in FIG. 2. Each of the conductive layers 42 overlaps and is connected to the plurality of memory cells MC in the X-axis direction.

The insulating film 43 is provided between the oxide semiconductor layer 41 and the conductive layer 42 in the X-Y plane. The insulating film 43 forms a gate insulating film of the memory transistor MTR. The insulating film 43 contains, for example, silicon and oxygen or nitrogen. The insulating film 43 may be a stacked film of a plurality of insulating films.

The field effect transistor 40 is a so-called surrounding gate transistor (SGT) in which a gate electrode surrounds a channel. The area of the semiconductor device can be reduced by SGT.

The field effect transistor having the channel layer including the oxide semiconductor has a lower off-leakage current than that of the field effect transistor provided on the semiconductor substrate 10. Therefore, for example, since the data stored in the memory cell MC can be stored for a long time, the number of times of the refresh operation can be reduced. In addition, since the field effect transistor having the channel layer including the oxide semiconductor can be formed by a low-temperature process, it is possible to reduce the application of thermal stress to the memory capacitor MCP.

The insulating layer 44 is provided on the insulating layer 33 and is provided below the conductive layer 42. The insulating layer 44 is provided between the plurality of field effect transistors 40. The insulating layer 44 contains, for example, silicon and oxygen or nitrogen.

The insulating layer 45 is provided on the insulating layer 44. The insulating layer 45 is provided between the plurality of conductive layers 42. The insulating layer 45 contains, for example, silicon and oxygen or nitrogen.

The insulating layer 46 is provided on the conductive layer 42 and on the insulating layer 45, and is provided below the insulating layer 54. The insulating layer 46 is provided on the insulating layer 45 between the plurality of field effect transistors 40. The insulating layer 46 contains, for example, silicon and oxygen or nitrogen.

The conductive oxide layer 51 is provided on the oxide semiconductor layer 41. The conductive oxide layer 51 contains, for example, a metal oxide such as indium-tin-oxide (ITO).

The conductive layer 52 is provided on the conductive oxide layer 51 and is electrically connected to the conductive oxide layer 51. The conductive layer 52 contains, for example, copper or tungsten.

The conductive layer 53 is provided between the conductive oxide layer 51 and the conductive layer 52. The conductive layer 53 is, for example, a metal compound layer and contains, for example, titanium and nitrogen. By forming the conductive layer 53, the diffusion of oxygen from the conductive oxide layer 51 to the conductive layer 52 can be reduced.

The conductive oxide layer 51, the conductive layer 52, and the conductive layer 53 form the conductor 50. The conductor 50 is electrically connected to the sense amplifier via the bit line BL. The conductor 50 has a function as a conductive pad for connecting the memory transistor MTR and the bit line BL, for example. A plurality of conductors 50 are provided corresponding to the plurality of field effect transistors 40. An insulating layer 54 is formed between the plurality of conductors 50. The insulating layer 54 contains, for example, silicon and oxygen or nitrogen.

The other end of the oxide semiconductor layer 41 in the Z-axis direction is connected to the conductive layer 52 via the conductive oxide layer 51 and the conductive layer 53, and functions as one of the source or the drain of the memory transistor MTR. The conductive oxide layer 51 functions as one of the source electrode or the drain electrode of the memory transistor MTR. The conductive oxide layer 51 contains a metal oxide in the same manner as that in the oxide semiconductor layer 41 of the field effect transistor 40, and thus the connection resistance between the memory transistor MTR and the bit line BL can be reduced.

The conductive layer 61 is provided on at least a part of the conductive layer 52 and is connected to the conductor 50. The conductive layer 61 forms the bit line BL as wiring. The conductive layer 61 includes, for example, copper or tungsten.

The insulating layer 62 is provided between the plurality of conductive layers 61. The insulating layer 62 is provided on the insulating layer 54. The insulating layer 62 may be provided on a part of the conductive layer 52. The insulating layer 62 contains, for example, silicon and oxygen or nitrogen.

The insulating layer 62 has a void 62S. The void 62S is provided on the insulating layer 54. The void 62S is provided, for example, between the plurality of conductive layers 61. The void 62S extends in the Y-axis direction, for example. The void 62S may have, for example, a hole shape in the X-Y plane. The void 62S may be filled with, for example, air.

The plurality of conductive layers 61 (bit lines BL) extend in the Y-axis direction and are parallel with each other, as shown in FIG. 2. Each of the conductive layers 61 overlaps and is connected to the plurality of memory cells MC when viewed in the Z-axis direction.

The plurality of memory cells MC may be formed in a zigzag manner in the X-Y plane as shown in FIG. 2. The memory cell MC connected to one of the plurality of word lines WL is shifted in the X-axis direction with respect to the memory cell MC connected to the adjacent word line WL. As a result, the integration degree of the memory cell MC can be increased.

The insulating layer 71 is provided on the conductive layer 61 and on the insulating layer 62. The insulating layer 71 contains, for example, silicon and oxygen or nitrogen.

The insulating layer 72 is provided on the insulating layer 62 and is provided below the insulating layer 71. The insulating layer 72 has a lower oxygen permeability than that of the insulating layer 62 or the insulating layer 71. The insulating layer 72 has a higher density than that of the insulating layer 62 or the insulating layer 71.

The insulating layer 72 contains silicon and oxygen. The thickness of the insulating layer 72 is, for example, 20 nm or more and 500 nm or less.

The conductor 81 is in contact with one of the plurality of conductive layers 61 by penetrating the insulating layer 71 and the insulating layer 72 in the Z-axis direction. The conductor 81 includes, for example, a metal such as copper or tungsten. The conductor 81 has a function as a contact. The conductor 81 may be a stack of a plurality of metal layers.

The conductor 82 is in contact with one of the plurality of conductive layers 42 by penetrating the insulating layer 46, the insulating layer 54, the insulating layer 62, the insulating layer 71, and the insulating layer 72 in the Z-axis direction. The conductor 82 has a function as a contact. The conductor 82 includes, for example, a metal such as copper or tungsten. The conductor 82 may be a stack of a plurality of metal layers.

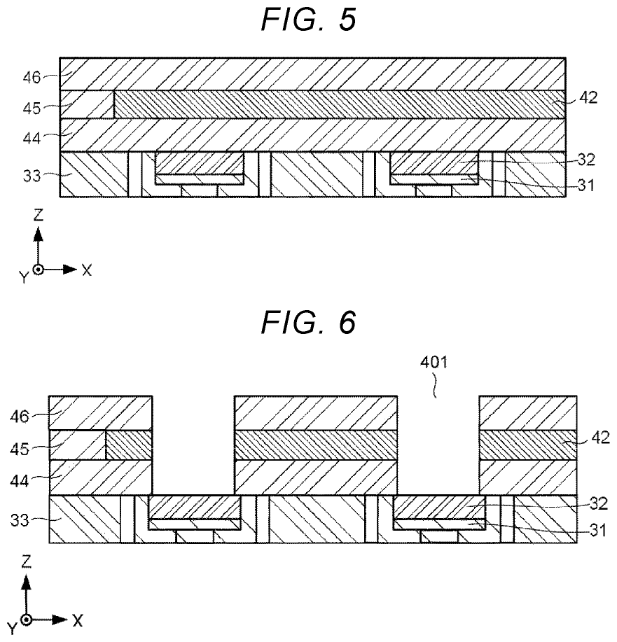

Next, a manufacturing method example of the first structural example of the memory cell array will be described with reference to FIGS. 5 to 16. FIGS. 5 to 16 are schematic cross-sectional views showing a manufacturing method example of the first structural example. FIGS. 5 to 16 show a part of the X-Z cross section. Here, the manufacturing process after the memory capacitor MCP is formed will be described.

As shown in FIG. 5, the insulating layer 44, the conductive layer 42, the insulating layer 45, and the insulating layer 46 are formed in this order on the conductive oxide layer 32. The conductive oxide layer 32 can be formed by, for example, using sputtering or an atomic layer deposition method (ALD). The conductive layer 42 can be formed by, for example, forming a conductive film by using sputtering or ALD and then partially erasing the conductive film by etching using, for example, a resist mask. The insulating layer 44, the insulating layer 45, and the insulating layer 46 can be formed by using, for example, a chemical vapor deposition method (CVD) or ALD.

Next, as shown in FIG. 6, an opening 401 that penetrates the stack of the insulating layer 44, the conductive layer 42, and the insulating layer 45 in the Z-axis direction is formed to partially expose the upper surface of the conductive oxide layer 32. The opening 401 can be formed by partially erasing the stack in the thickness direction by etching using, for example, a resist mask.

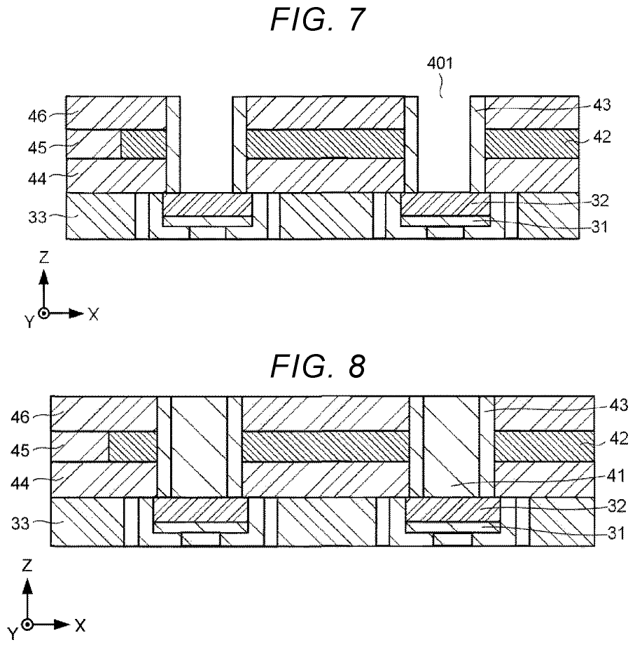

Next, as shown in FIG. 7, the insulating film 43 is formed on the inner surface of the opening 401. The insulating film 43 can be formed by, for example, forming an insulating film using CVD or ALD and then partially erasing the insulating film 43 in the thickness direction by reactive ion etching (RIE) to partially expose the upper surface of the conductive oxide layer 32 and the upper surface of the insulating layer 46.

Next, as shown in FIG. 8, the oxide semiconductor layer 41 that fills the opening 401 is formed. The oxide semiconductor layer 41 is formed, for example, by forming an oxide semiconductor film in the opening 401 using sputtering or ALD, and then partially erasing the oxide semiconductor film in the thickness direction by RIE to expose the upper surface of the insulating layer 46.

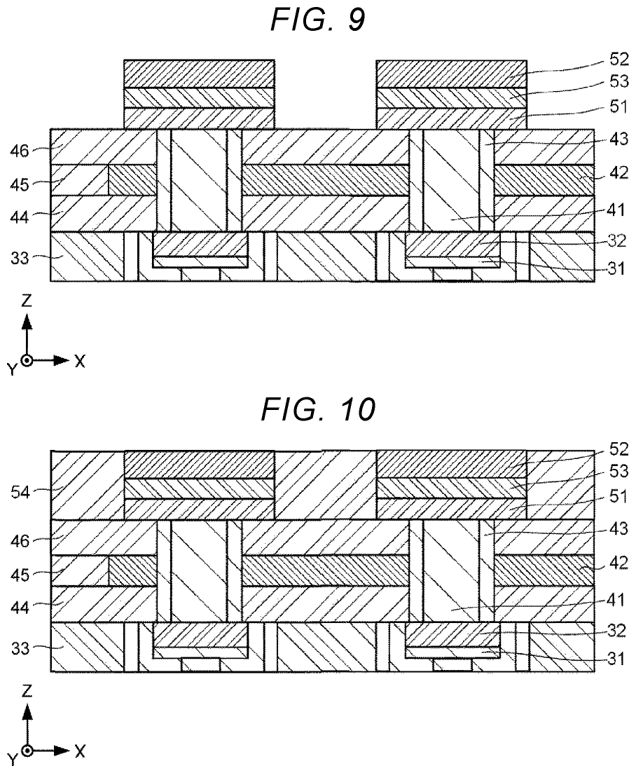

Next, as shown in FIG. 9, a conductive oxide layer 51, a conductive layer 53, and a conductive layer 52 are formed on the oxide semiconductor layer 41. The conductive oxide layer 51, the conductive layer 53, and the conductive layer 52 can be formed, for example, by forming a stacked film using sputtering or ALD and then partially erasing the stacked film by etching using, for example, a resist mask.

Next, as shown in FIG. 10, the insulating layer 54 is formed on the insulating layer 46. The insulating layer 46 can be formed by, for example, forming an insulating film using CVD or ALD, and then partially erasing the insulating layer 46 in the thickness direction by RIE to expose the upper surface of the conductive layer 52.

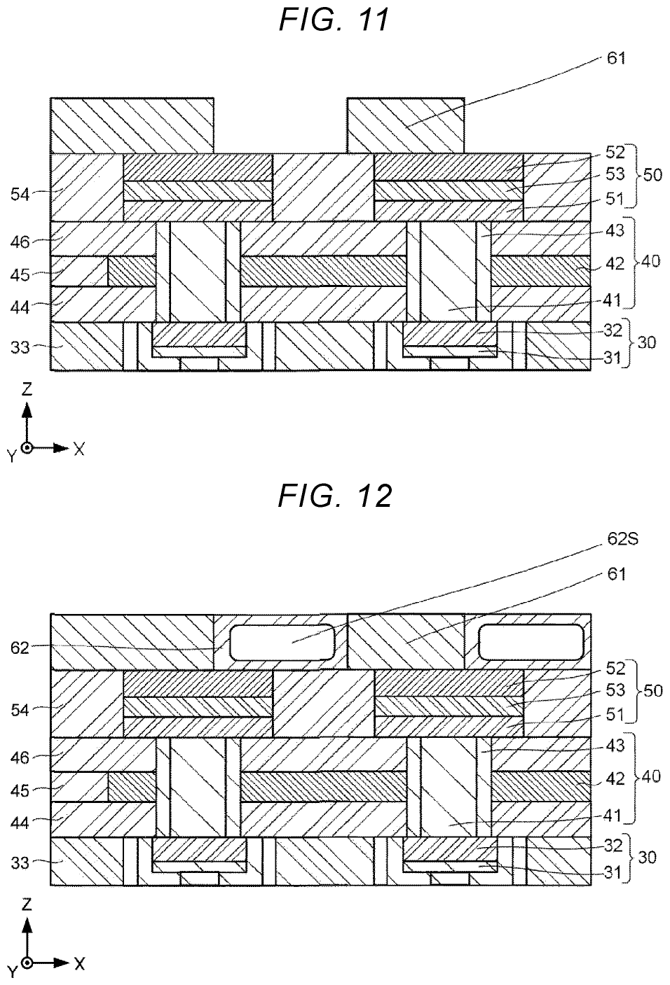

Next, as shown in FIG. 11, the conductive layer 61 is formed on at least a part of the conductive layer 52. The conductive layer 61 can be formed, for example, by forming a conductive film by using sputtering or ALD and then partially erasing the conductive film by etching using, for example, a resist mask.

Next, as shown in FIG. 12, the insulating layer 62 is formed between the plurality of conductive layers 61. The insulating layer 62 can be formed by forming a lower insulating layer using CVD or ALD, forming a mask layer on the lower insulating layer using, for example, a photolithography technique, partially erasing the lower insulating layer by etching such as dry etching or wet etching using the mask layer to form a recess, forming an upper insulating layer having a worse coverage (step coverage property) than that of the lower insulating layer on the lower insulating layer and the recess using CVD or ALD, and flattening the upper insulating layer by RIE or chemical mechanical polishing (CMP). In this manner, the void 62S can be formed between the upper insulating layer and the lower insulating layer.

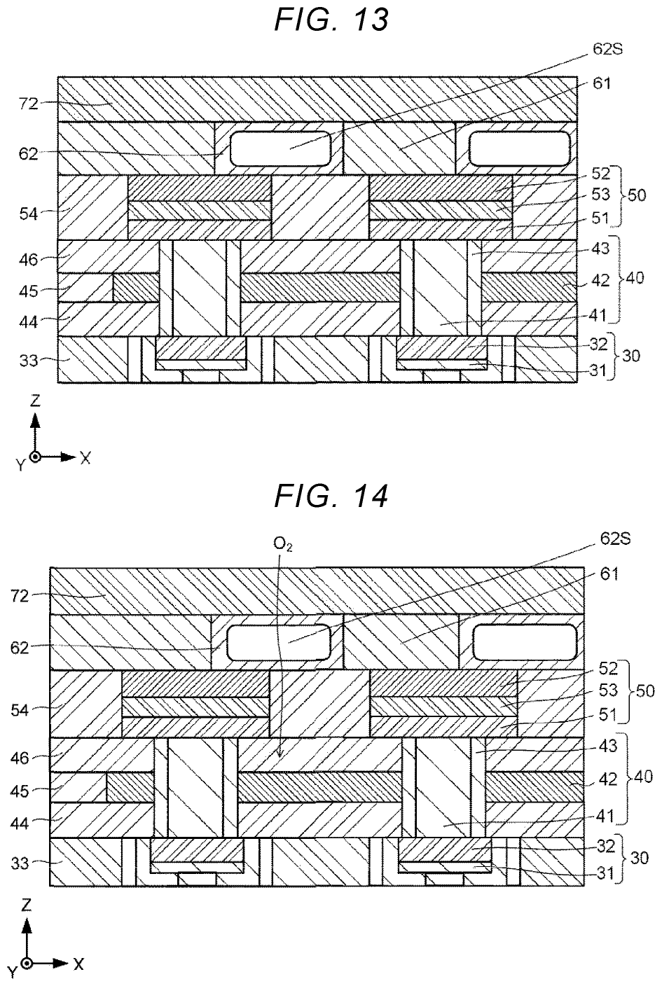

Next, as shown in FIG. 13, the insulating layer 72 is formed on the insulating layer 62. The insulating layer 72 can be formed using, for example, CVD or ALD. The insulating layer 72 is formed at a temperature of, for example, 200° C. or higher and 400° C. or lower.

Next, as shown in FIG. 14, the oxygen (02) is supplied to the oxide semiconductor layer 41 through the insulating layer 72 and the void 62S by performing heat treatment in an atmosphere containing oxygen. The heat treatment is performed, for example, at a temperature of 400° C. or higher and 500° C. or lower and a pressure of 100 Torr or higher and 700 Torr or lower for 5 minutes or longer and 30 minutes or shorter.

When the memory cell array is formed, oxygen is easily desorbed from the oxide semiconductor layer 41. When oxygen is desorbed, the threshold voltage of the field effect transistor 40 (memory transistor MTR) shifts in the negative direction, and the electrical characteristics of the memory transistor MTR deteriorate. Therefore, by performing heat treatment in an oxygen atmosphere after the formation of the oxide semiconductor layer 41, the shift of the threshold voltage of the memory transistor MTR can be reduced.

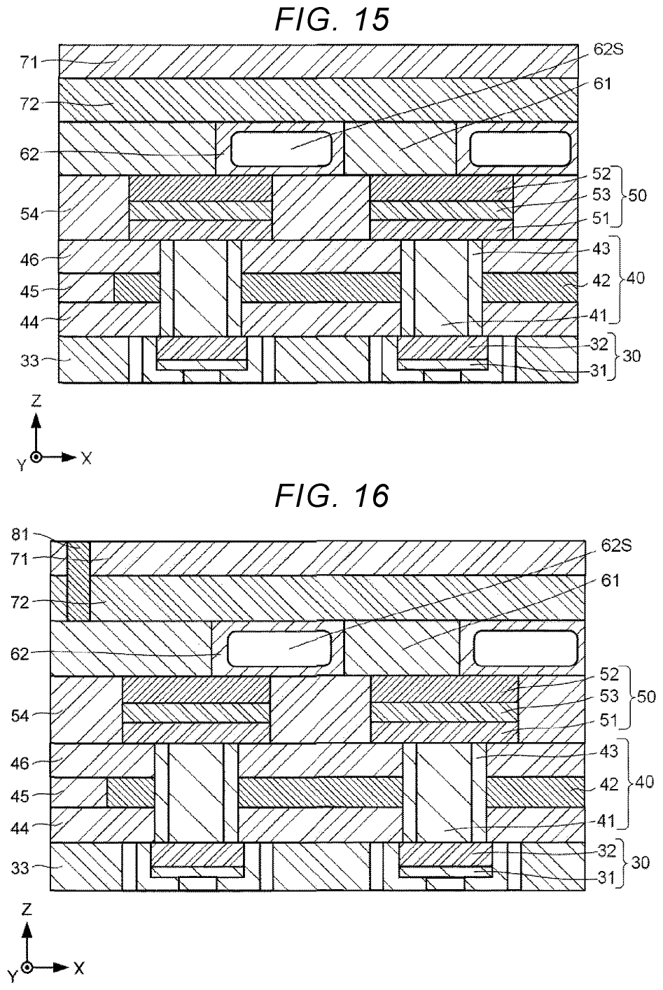

Next, as shown in FIG. 15, the insulating layer 71 is formed on the insulating layer 72. The insulating layer 71 can be formed using, for example, CVD or ALD. The insulating layer 71 is formed at a temperature of, for example, 200° C. or higher and 400° C. or lower. The thickness of the insulating layer 71 is, for example, 20 nm or more and 500 nm or less.

By controlling the forming conditions of the insulating layer 71 and the insulating layer 72, the density of the insulating layer 72 can be made higher than the density of the insulating layer 71. Accordingly, the insulating layer 72 can have a lower oxygen permeability than that of the insulating layer 71.

Next, as shown in FIG. 16, the conductor 81 is formed, and the conductor 82 shown in FIG. 3 is formed. The conductor 81 and the conductor 82 can be formed by forming the conductive layers to form openings in the insulating layer 46, the insulating layer 54, the insulating layer 62, the insulating layer 71, and the insulating layer 72 and to fill the openings. As a method for forming the other elements, it is possible to use a known method. The manufacturing method example of the first structural example is as described above.

The insulating layer 71 can be formed by, for example, CVD or ALD, but since oxygen is easily desorbed from the oxide semiconductor layer 41 even by heat generated during the formation, it is preferable to perform heat treatment in an oxygen atmosphere after the formation of the insulating layer 71.

However, when the heat treatment is performed after the formation of the insulating layer 71 without forming the insulating layer 72, the oxygen supply efficiency is too high, and thus the conductive layer 52 or the conductive layer 61 is likely to be oxidized. Therefore, operational failure of the memory transistor MTR is caused and the reliability of the semiconductor device decreases.

Conversely, in the first structural example of the memory cell array, the insulating layer 72 having lower oxygen permeability than that of the insulating layer 62 or the insulating layer 71 is provided, so that the oxidation of the conductive layer 52 and the conductive layer 61 can be reduced. As a result, it is possible to reduce a decrease in reliability of the semiconductor device.

### First Modification Example of First Structural Example

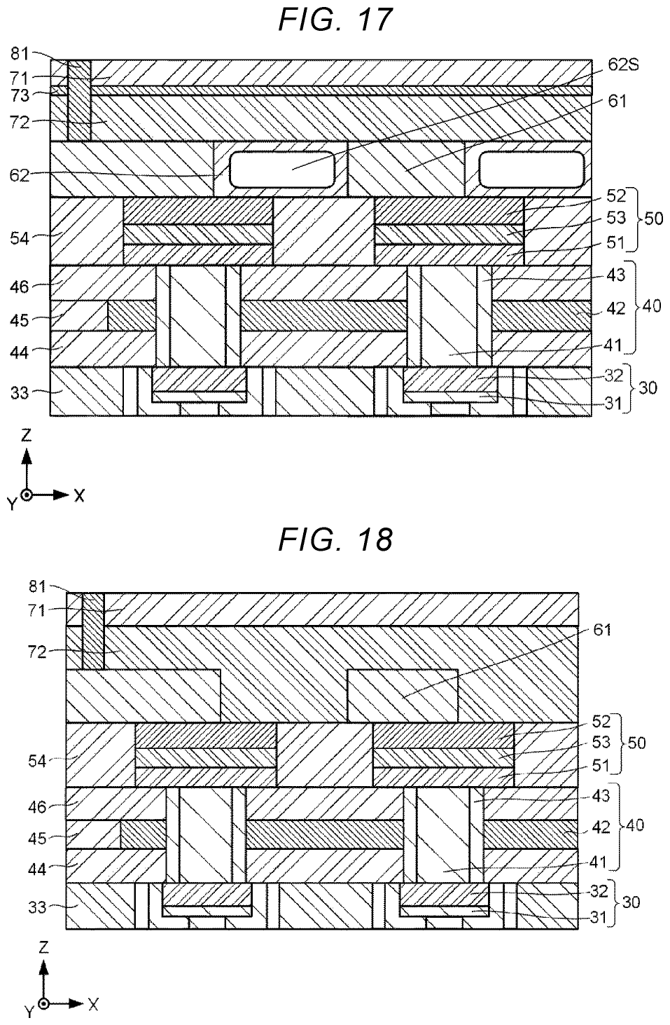

FIG. 17 is a schematic cross-sectional view showing a first modification example of the first structural example. FIG. 17 shows a part of the X-Z cross section. As compared to the configuration shown in FIG. 4, the memory cell array shown in FIG. 17 has a configuration different from the configuration shown in FIG. 4 in that a barrier film 73 is provided. Hereinafter, portions different from those in FIG. 4 will be described, and other portions can be appropriately referred to in the description of FIG. 4.

The barrier film 73 is provided between the insulating layer 71 and the insulating layer 72. The barrier film 73 has a function of reducing the transfer of oxygen and hydrogen. For example, when hydrogen moves to the oxide semiconductor layer 41, the threshold voltage of the memory transistor MTR may shift. The barrier film 73 preferably has lower permeability of oxygen or hydrogen than that of the insulating layer 71 or the insulating layer 72. The barrier film 73 contains, for example, at least one element of aluminum, hafnium, zirconium, tungsten, tantalum, titanium, silicon, molybdenum, or zinc, and oxygen or nitrogen. The barrier film 73 is, for example, an insulating layer. The conductor 81 and the conductor 82 penetrate the barrier film 73.

The barrier film 73 can be formed on the insulating layer 72 by, for example, CVD, ALD, or sputtering after the heat treatment and before the insulating layer 71 is formed. The insulating layer 71 is formed on the barrier film 73 after the barrier film 73 is formed. The barrier film 73 may be continuously formed in the same chamber as that in the insulating layer 72. The barrier film 73 may be continuously formed in the same chamber as that in the insulating layer 72, for example, after the chamber is heated at a temperature of 300° C. or higher.

By forming the barrier film 73, the desorption of oxygen to the upper portion of the barrier film 73 after the heat treatment can be reduced. In addition, the barrier film 73 can reduce the intrusion of hydrogen into the lower portion of the barrier film 73 after the heat treatment by forming the barrier film 73. As a result, it is possible to reduce a decrease in reliability of the semiconductor device.

### Second Modification Example of First Structural Example

FIG. 18 is a schematic cross-sectional view showing a second modification example of the first structural example. FIG. 18 shows a part of the X-Z cross section. As compared to the configuration shown in FIG. 4, the memory cell array shown in FIG. 18 has a configuration different from the configuration shown in FIG. 4 in that the insulating layer 62 is not provided and the insulating layer 72 is provided. Hereinafter, portions different from those in FIG. 4 will be described, and other portions can be appropriately referred to in the description of FIG. 4.

When the insulating layer 62 is not provided, the insulating layer 72 extends between the plurality of conductive layers 61. Therefore, the insulating layer 72 is provided on the conductive layer 52, on the insulating layer 54, and on the conductive layer 61, and is provided in contact with the side surface of the conductive layer 61. The insulating layer 72 can be formed, for example, after the conductive layer 61 is formed, on the conductive layer 52, on the insulating layer 54, and on the conductive layer 61 using, for example, CVD or ALD, as in FIG. 11.

By extending the insulating layer 72 between the plurality of conductive layers 61, the effect of reducing the oxidation of the side surfaces of the conductive layers 61 by the heat treatment can be improved. As a result, it is possible to reduce a decrease in reliability of the semiconductor device.

### Third Modification Example of First Structural Example

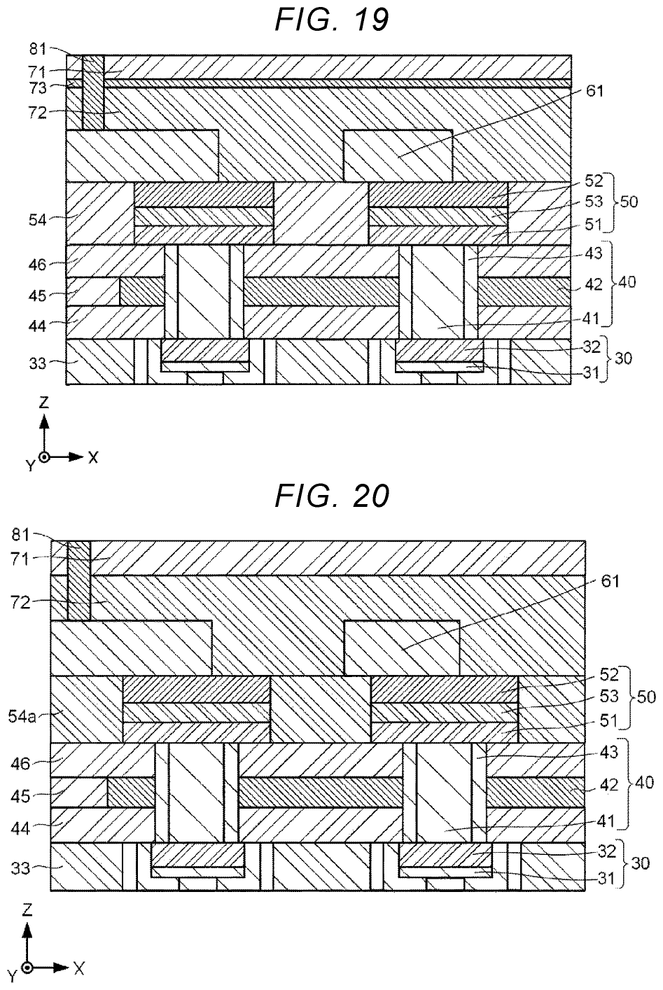

FIG. 19 is a schematic cross-sectional view showing a third modification example of the first structural example. FIG. 19 shows a part of the X-Z cross section. As compared to the configuration shown in FIG. 4, the memory cell array shown in FIG. 19 has a configuration different from the configuration shown in FIG. 4 in that the barrier film 73 is provided, the insulating layer 62 is not provided, and the insulating layer 72 is provided. For other portions, the descriptions of FIGS. 17 and 18 can be appropriately referred to.

By forming the barrier film 73, the desorption of oxygen from the upper portion of the barrier film 73 after the heat treatment can be reduced. In addition, by forming the barrier film 73, the intrusion of hydrogen into the lower portion of the barrier film 73 after the heat treatment can be reduced. As a result, it is possible to reduce a decrease in reliability of the semiconductor device.

By extending the insulating layer 72 between the plurality of conductive layers 61, the effect of reducing the oxidation of the side surfaces of the conductive layers 61 by the heat treatment can be improved. As a result, it is possible to reduce a decrease in reliability of the semiconductor device.

### Fourth Modification Example of First Structural Example

FIG. 20 is a schematic cross-sectional view showing a fourth modification example of the first structural example. FIG. 20 shows a part of the X-Z cross section. The memory cell array shown in FIG. 20 has a configuration in which the insulating layer 54a is provided instead of the insulating layer 54, as compared with the configuration shown in FIG. 18. Hereinafter, portions different from those in FIG. 18 will be described, and other portions can be appropriately referred to in the description of FIG. 18.

The insulating layer 54a is provided on the insulating layer 46 and is provided between the plurality of conductors 50. Therefore, the insulating layer 54a is in contact with the side surface of the conductive oxide layer 51, the side surface of the conductive layer 52, and the side surface of the conductive layer 53.

The insulating layer 54a has lower oxygen permeability than that of the insulating layer 54 and has lower oxygen permeability than that of the insulating layer 71. The insulating layer 54a has a higher density than that of the insulating layer 54 and has a higher density than that of the insulating layer 71. The insulating layer 54a contains silicon and oxygen. The insulating layer 54a can be formed of the same material and by the same method as those of the insulating layer 72.

The effect of reducing the oxidation of the side surface of the conductor 50 by the heat treatment can be improved by the insulating layer 54a. As a result, it is possible to reduce a decrease in reliability of the semiconductor device.

### Fifth Modification Example of First Structural Example

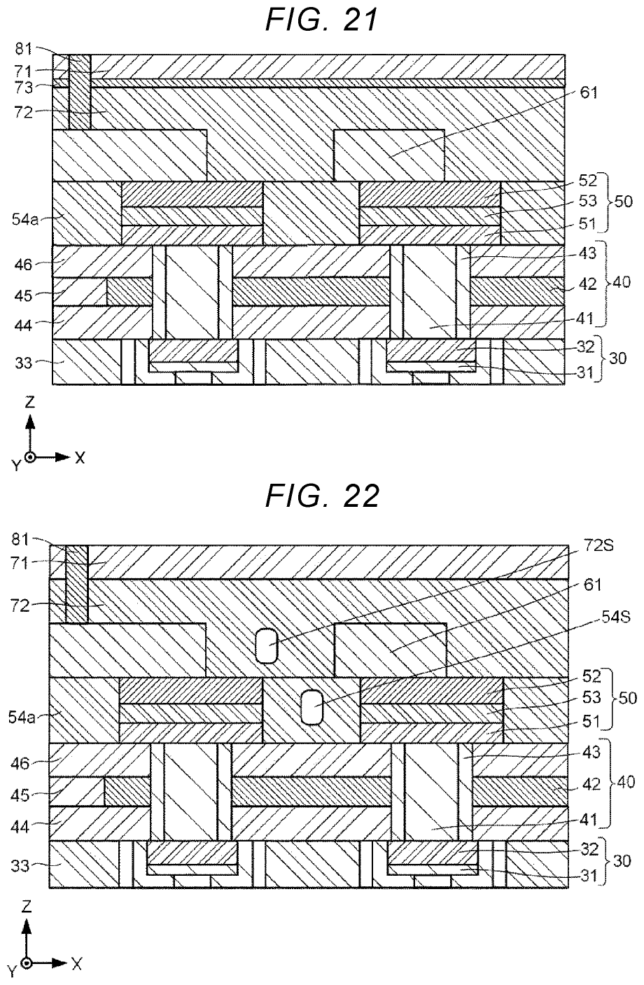

FIG. 21 is a schematic cross-sectional view showing a fifth modification example of the first structural example. FIG. 21 shows a part of the X-Z cross section. The memory cell array shown in FIG. 21 has a configuration different from the configuration having the barrier film 73 shown in FIG. 20, as compared with the configuration shown in FIG. 20. The description of the barrier film 73 can be appropriately referred to in FIG. 18, and the description of the other portions can be appropriately referred to in FIG. 20.

The formation of the barrier film 73 makes it possible to reduce the desorption of oxygen after the heat treatment. In addition, the barrier film 73 can reduce the intrusion of hydrogen after the heat treatment. As a result, it is possible to reduce a decrease in reliability of the semiconductor device. Sixth Modification Example of First Structural Example

FIG. 22 is a schematic cross-sectional view showing a sixth modification example of the first structural example. FIG. 22 shows a part of the X-Z cross section. The memory cell array shown in FIG. 22 has a configuration in which the insulating layer 54a has the void 54S and the insulating layer 72 has the void 72S, as compared with the configuration shown in FIG. 20. Hereinafter, portions different from those in FIG. 20 will be described, and other portions can be appropriately referred to in the description of FIG. 20.

The void 54S is provided, for example, between the plurality of conductors 50. The void 54S is provided on the insulating layer 46. The void 54S is preferably separated from the conductor 50. The void 54S extends in the Y-axis direction, for example. The void 54S may have, for example, a hole shape in the X-Y plane. The void 54S may be filled with, for example, air. The void 54S can be formed by the same method as that of the void 62S, for example.

The void 72S is provided, for example, between the plurality of conductive layers 61. The void 72S may be provided on the insulating layer 54a. The void 72S is preferably separated from the conductive layer 61. The void 72S extends in the Y-axis direction, for example. The void 72S may have, for example, a hole shape in the X-Y plane. The void 72S may be filled with, for example, air. The void 72S can be formed by the same method as that of the void 62S, for example.

By forming the voids 54S and the voids 72S, the oxidation of the conductor 50 and the conductive layer 61 can be reduced, and the supply efficiency of oxygen to the oxide semiconductor layer 41 by the heat treatment can be improved.

### Seventh Modification Example of First Structural Example

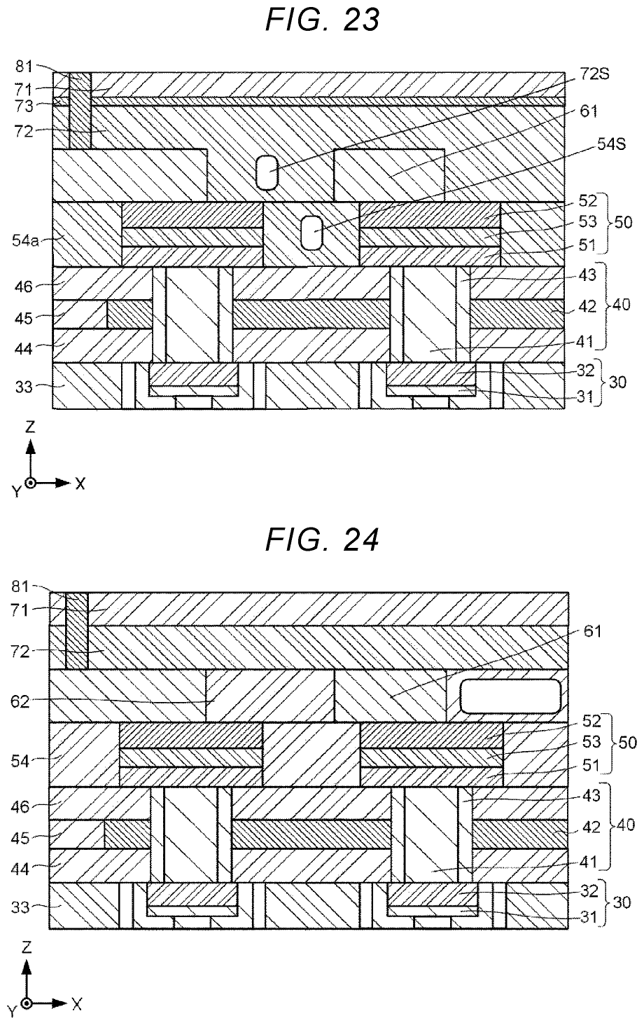

FIG. 23 is a schematic cross-sectional view showing a seventh modification example of the first structural example. FIG. 23 shows a part of the X-Z cross section. As compared to the configuration shown in FIG. 22, the memory cell array shown in FIG. 23 has a configuration different from the configuration shown in FIG. 22 in that the barrier film 73 is provided. The description of the barrier film 73 can be appropriately referred to in FIG. 18, and the description of the other portions can be appropriately referred to in FIG. 22.

The formation of the barrier film 73 makes it possible to reduce the desorption of oxygen after the heat treatment. In addition, the barrier film 73 can reduce the intrusion of hydrogen after the heat treatment. As a result, it is possible to reduce a decrease in reliability of the semiconductor device.

### Eighth Modification Example of First Structural Example

FIG. 24 is a schematic cross-sectional view showing an eighth modification example of the first structural example. FIG. 24 shows a part of the X-Z cross section. As compared to the configuration shown in FIG. 4, the memory cell array shown in FIG. 24 has a configuration different from the configuration shown in FIG. 4 in that the void 62S is not provided. For other portions, the description in FIG. 4 can be appropriately referred to.

Even when the void 62S is not provided, the oxidation of the conductor 50 and the conductive layer 61 can be reduced, and oxygen can be supplied to the oxide semiconductor layer 41. As a result, it is possible to reduce a decrease in reliability of the semiconductor device.

### Ninth Modification Example of First Structural Example

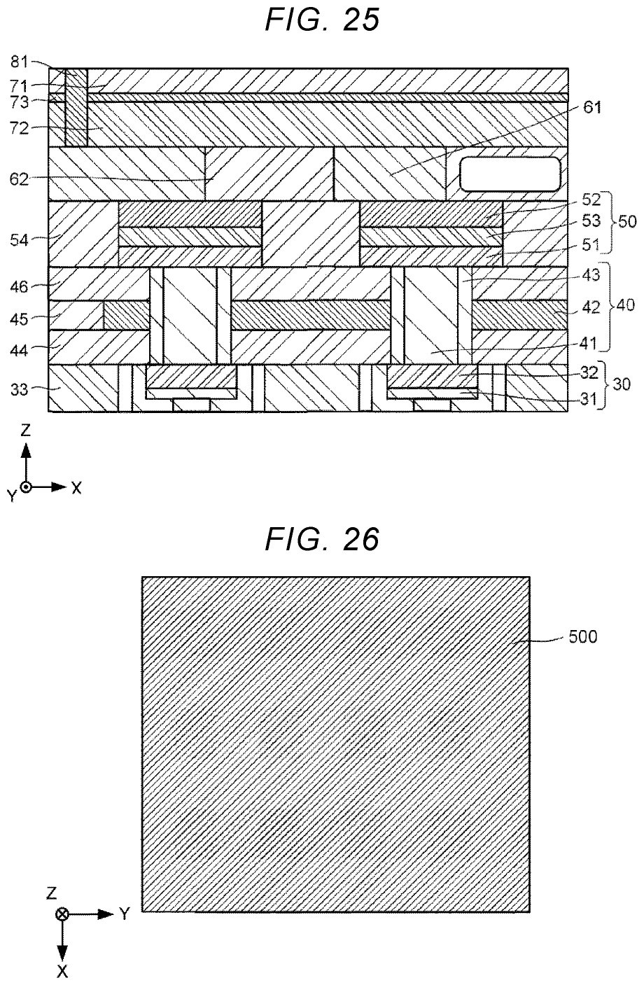

FIG. 25 is a schematic cross-sectional view showing a ninth modification example of the first structural example. FIG. 25 shows a part of the X-Z cross section. As compared to the configuration shown in FIG. 24, the memory cell array shown in FIG. 25 has a configuration different from the configuration shown in FIG. 24 in that the barrier film 73 is provided. The description of the barrier film 73 can be appropriately referred to in FIG. 18, and the description of the other portions can be appropriately referred to in FIG. 24.

By forming the barrier film 73, the desorption of oxygen to the upper portion of the barrier film 73 after the heat treatment can be reduced. In addition, the barrier film 73 can reduce the intrusion of hydrogen into the lower portion of the barrier film 73 after the heat treatment by forming the barrier film 73. As a result, it is possible to reduce a decrease in reliability of the semiconductor device.

It is possible to appropriately combine the first modification example to the ninth modification example.

### Second Structural Example of Memory Cell Array

FIGS. 26 to 30 are plan schematic views showing the manufacturing method example of the second structural example of the memory cell array of the embodiment. FIGS. 26 to 30 show a part of the X-Y plane. In the second structural example, the method of forming the conductor 50 is different from that in the first structural example, as compared with the first structural example. In the following, portions different from that of the first structural example will be described, and the description of the first structural example can be appropriately referred to for the other portions.

First, the memory capacitor MCP and the memory transistor MTR (field effect transistor 40) are formed in the same manner as that in the manufacturing method example of the first structural example. Here, the drawings are not shown for convenience.

Next, as shown in FIG. 26, a stacked film 500 of conductive films for forming the conductive oxide layer 51, the conductive layer 52, and the conductive layer 53 is formed. The stacked film 500 can be formed by, for example, sequentially stacking the conductive oxide layer 51, the conductive layer 53, and the conductive layer 52 for forming the conductive film using sputtering or ALD.

Next, as shown in FIG. 27, the mask layer 55 is formed on the stacked film 500. The plurality of mask layers 55 extend in the X-axis direction, and are separated in the Y-axis direction, for example. The mask layer 55 contains, for example, a resin material such as polyethylene polyol (PEP). The mask layer 55 can be formed by, for example, forming a resin film using a coating method and then partially erasing the resin film in the thickness direction by RIE to partially expose the upper surface of the stacked film 500.

When a plurality of mask layers 55 are formed by partially erasing the resin film by RIE, the mask layer 55 (mask layer 55a) located at the end portion in the Y-axis direction may have a larger width in the Y-axis direction than that of the mask layer 55 (mask layer 55b) that is located further inward than the mask layer 55 at the end portion. This is because scraps of the resin film are likely to occur at the end portion, and the scraps are deposited on the side surface of the mask layer 55 at the end portion.

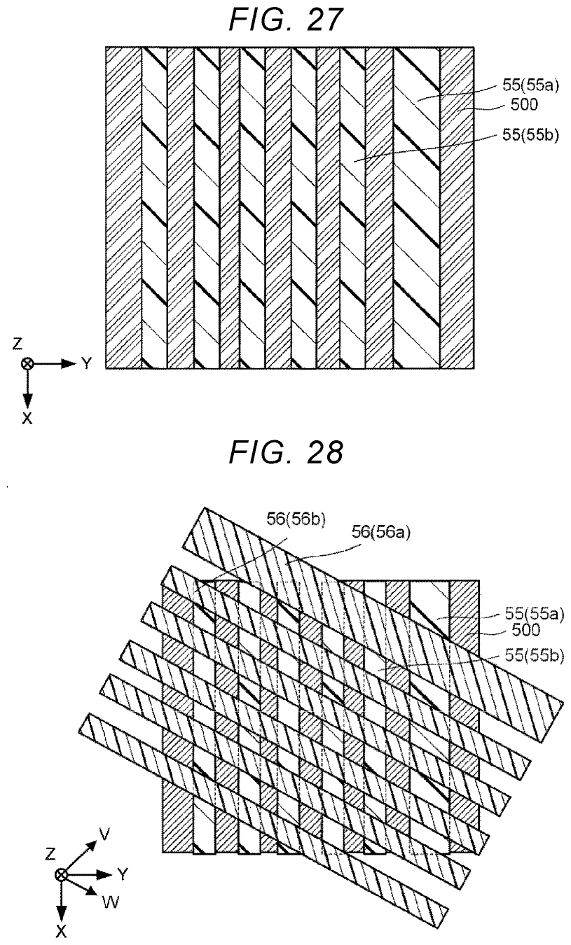

Next, as shown in FIG. 28, the mask layer 56 is formed on the mask layer 55. For example, the plurality of mask layers 56 are separated in the V-axis direction, and extend in the W-axis direction. The V-axis direction and the W-axis direction are any directions different from the X-axis direction and the Y-axis direction in the X-Y plane. Therefore, the V-axis and the W-axis intersect the X-axis, intersect the Y-axis, and intersect the Z-axis. The W-axis direction is different from the V-axis direction. The mask layer 56 contains, for example, a resin material such as PEP. The mask layer 56 can be formed by, for example, forming a resin film using a coating method, partially erasing the resin film in the thickness direction by RIE to partially expose the upper surface of the stacked film 500 while the mask layer 55 remains.

When a plurality of mask layers 56 are formed by partially erasing the resin film by RIE, the mask layer 56 (mask layer 56a) located at the end portion in the V-axis direction may have a larger width in the V-axis direction than that of the mask layer 56 (mask layer 56b) that is located further inward than the mask layer 56a at the end portion. This is because scraps of resin film are likely to occur at the end portion, and the scraps are deposited on the side surface of the mask layer 56 at the end portion.

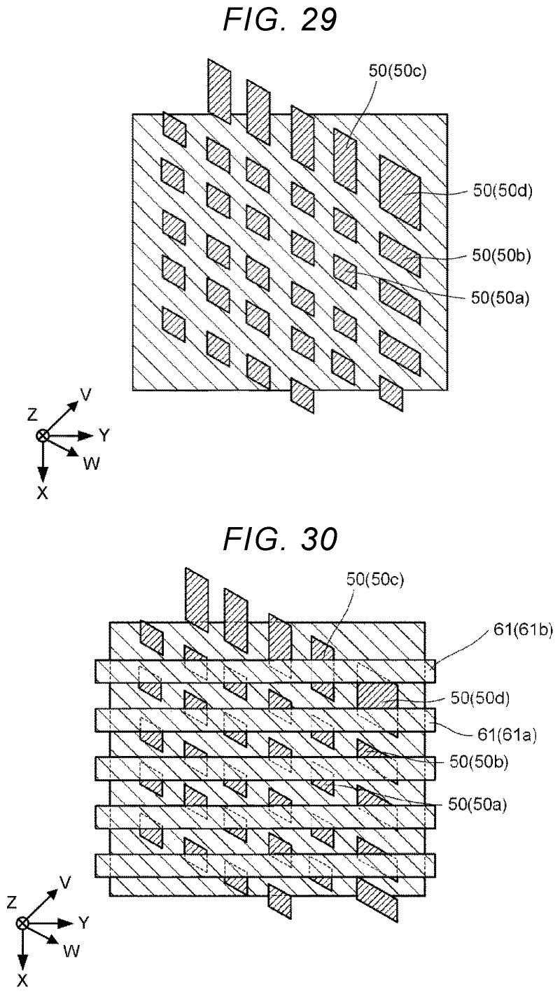

Next, as shown in FIG. 29, the stacked film 500 is partially erased by etching such as dry etching or wet etching using the mask layer 55 and the mask layer 56, and thus only a portion of the stacked film 500 overlapping the intersection portion between the mask layer 55 and the mask layer 56 remains to form a plurality of conductors 50.

The plurality of conductors 50 include a conductor 50a, a conductor 50b, a conductor 50c, and a conductor 50d. The conductors 50a to 50d extend in the X-axis direction and the W-axis direction.

The conductor 50a is disposed further inward than each of the conductor 50b, the conductor 50c, and the conductor 50d in at least one direction of the X-axis direction or the W-axis direction.

The conductor 50b is disposed at an end portion in the W-axis direction. The conductor 50b has a length in the W-axis direction larger than that of the conductor 50a. The length of the conductor 50b in the W-axis direction is preferably 1.05 times or more than the length of the conductor 50a in the W-axis direction. In addition, in the X-Y plane, the contact area between the conductor 50b and the conductive layer 61 is larger than the contact area between the conductor 50a and the conductive layer 61.

The conductor 50c is disposed at an end portion in the X-axis direction. The conductor 50c has a length in the X-axis direction larger than that of the conductor 50a. The length of the conductor 50c in the X-axis direction is preferably 1.05 times or more than the length of the conductor 50a in the X-axis direction. In addition, in the X-Y plane, the contact area between the conductor 50c and the conductive layer 61 is larger than the contact area between the conductor 50a and the conductive layer 61.

The conductor 50d is disposed at an end portion in the X-axis direction and is disposed at an end portion in the W-axis direction. The conductor 50d has a length in the X-axis direction larger than that of the conductor 50a. The conductor 50d has a larger length in the W-axis direction than that of the conductor 50a. The length of the conductor 50d in the X-axis direction is preferably 1.05 times or more than the length of the conductor 50a in the X-axis direction. A length of the conductor 50d in the W-axis direction is preferably 1.05 times or more than a length of the conductor 50a in the W-axis direction. In addition, in the X-Y plane, the contact area between the conductor 50d and the conductive layer 61 is larger than the contact area between the conductor 50a and the conductive layer 61.

Thereafter, as shown in FIG. 30, the conductive layer 61 is formed. The plurality of conductive layers 61 have a conductive layer 61a and a conductive layer 61b. The conductive layer 61a and the conductive layer 61b are separated in the X-axis direction and extend in the Y-axis direction.

The conductive layer 61a is disposed further inward than the conductive layer 61b in the X-axis direction. The conductive layer 61a is connected to, for example, the conductor 50a. The conductive layer 61a has a function as a bit line BL.

The conductive layer 61b is disposed at an end portion in the X-axis direction. The conductive layer 61b is connected to the conductor 50c or the conductor 50d. The conductive layer 61b has a function as a dummy bit line.

It is preferable that the conductive layer 61a is connected to only one of the conductor 50b, the conductor 50c, and the conductor 50d at one end portion in the Y-axis direction. As a result, it is possible to reduce a short circuit between the adjacent bit lines BL.

By forming the conductor 50 using a plurality of mask layers, the plurality of conductors 50 can be easily formed. Furthermore, when the conductor 50 having a large area is formed at the end portion, it is possible to reduce short circuit between the bit lines BL by controlling the disposition of the conductive layer 61.

### Modification Example of Second Structural Example

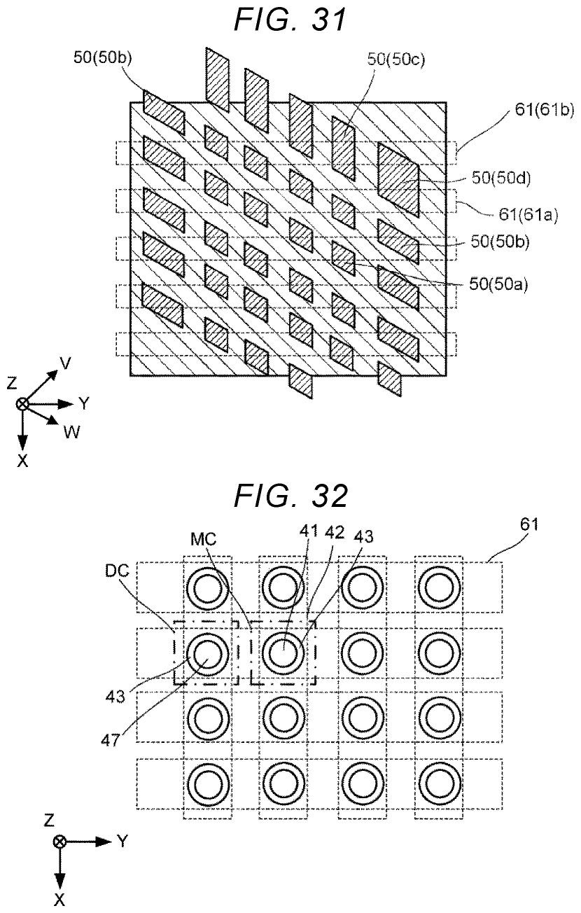

FIG. 31 is a schematic cross-sectional view showing a modification example of the second structural example. FIG. 31 shows a part of the X-Y plane. As compared to the configuration shown in FIG. 30, the memory cell array shown in FIG. 31 has a configuration different from the configuration shown in FIG. 30 in that the conductors 50 are provided, which has different areas from the conductors 50a at both ends in at least one direction of the X-axis direction or the W-axis direction. Hereinafter, portions different from those in FIG. 30 will be described, and the description of the other portions can be appropriately referred to from FIG. 30. In FIG. 31, for convenience, the conductive layer 61 is shown by a dotted line.

FIG. 30 shows an example in which the conductor 50b is provided at both ends in the W-axis direction. The present disclosure is not limited thereto, and in a modification example of the second structural example, the conductor 50c may be provided at both ends in the X-axis direction, or the conductor 50d may be provided at both ends in the X-axis direction and both ends in the W-axis direction. It is preferable that the conductive layer 61a is connected to only one of the conductor 50b, the conductor 50c, and the conductor 50d at each of the end portions in the Y-axis direction. As a result, it is possible to reduce a short circuit between the adjacent bit lines BL.

Also in the configuration shown in FIG. 31, the plurality of conductors 50 can be easily formed. Furthermore, when the conductor 50 having a large area is formed at the end portion, it is possible to reduce short circuit between the bit lines BL by controlling the disposition of the conductive layer 61.

### Third Structural Example of Memory Cell Array

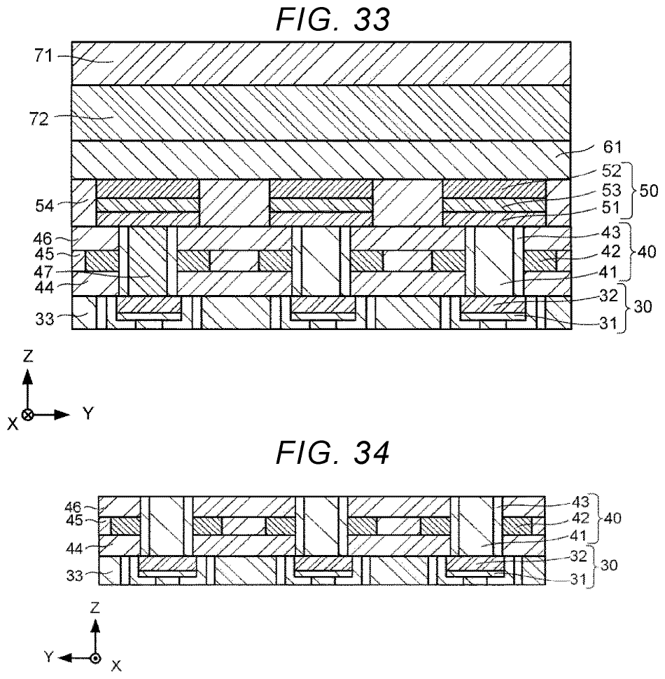

FIG. 32 is a plan schematic view showing a third structural example of the memory cell array. FIG. 33 is a schematic cross-sectional view showing a third structural example of the memory cell array. FIG. 32 shows a part of the X-Y plane. FIG. 32 shows a part of the Y-Z cross section. Hereinafter, portions different from that of the first structural example or the second structural example will be described, and other portions can be appropriately referred to from the description of the first structural example or the second structural example. In FIG. 32, for convenience, the conductive layer 42 and the conductive layer 61 are shown by dotted lines.

As shown in FIG. 32, a third structural example has a memory cell MC and a dummy cell DC. The memory cell MC connected to one of the plurality of word lines WL is arranged along the X-axis direction. In addition, the plurality of memory cells MC are not limited thereto, and may be formed in a zigzag manner in the X-Y plane as in FIG. 2. In FIG. 32, the width of the conductive layer 42 in the Y-axis direction is constant, but the present disclosure is not limited thereto, and as in FIG. 2, the region that does not overlap the field effect transistor 40 when viewed in the Y-axis direction may have a smaller width in the Y-axis direction than that of the region that overlaps the field effect transistor 40.

The plurality of memory cells MC are disposed further inward than the dummy cell DC in the X-axis direction and the Y-axis direction of the memory cell array. For other descriptions of the memory cell MC, the description of the first structural example can be appropriately referred to.

The dummy cell DC is disposed at an end portion of the memory cell array in at least one direction of the X-axis direction or the Y-axis direction. The plurality of dummy cells DC may be disposed at an end portion of the memory cell array in the X-axis direction and an end portion of the memory cell array in the Y-axis direction. As shown in FIG. 33, the dummy cell DC has the insulating layer 47 instead of the oxide semiconductor layer 41 in the memory cell MC, for example.

The insulating layer 47 is, for example, a columnar body extending in the Z-axis direction. The insulating layer 47 penetrates the conductive layer 42 in the Z-axis direction. The insulating layer 47 contains, for example, silicon or aluminum and oxygen or nitrogen. The insulating layer 47 may be, for example, a silicon oxide layer or an aluminum oxide layer. In addition, the insulating layer 47 may be an air gap.

At the end portion of the memory cell array, the opening 401 for forming the oxide semiconductor layer 41 may be formed without penetrating the conductive layer 42. Therefore, a short circuit of the oxide semiconductor layer 41 with the conductive layer 42 is caused.

Conversely, in the third structural example of the memory cell array, the reliability of the semiconductor device can be prevented from being decreased by forming the dummy cell DC instead of the memory cell MC at the end portion of the memory cell array. For example, by providing the insulating layer 47, it is possible to reduce a short circuit between the oxide semiconductor layer 41 and the conductive layer 42.

Next, a manufacturing method example of the third structural example of the memory cell array will be described with reference to FIG. 34 to FIG. 37. FIGS. 34 to 37 are schematic cross-sectional views showing a manufacturing method example of the third structural example. FIGS. 34 to 37 show a part of the Y-Z cross section.

The insulating layer 44, the conductive layer 42, and the insulating layer 45 are formed in this order on the conductive oxide layer 32 by the same method as that of the manufacturing method example of the first structural example, and then the opening 401 penetrating the stack of the insulating layer 44, the conductive layer 42, and the insulating layer 45 in the Z-axis direction is formed to partially expose the upper surface of the conductive oxide layer 32, and the insulating film 43 and the oxide semiconductor layer 41 are formed in the opening 401 in this order as shown in FIG. 34.

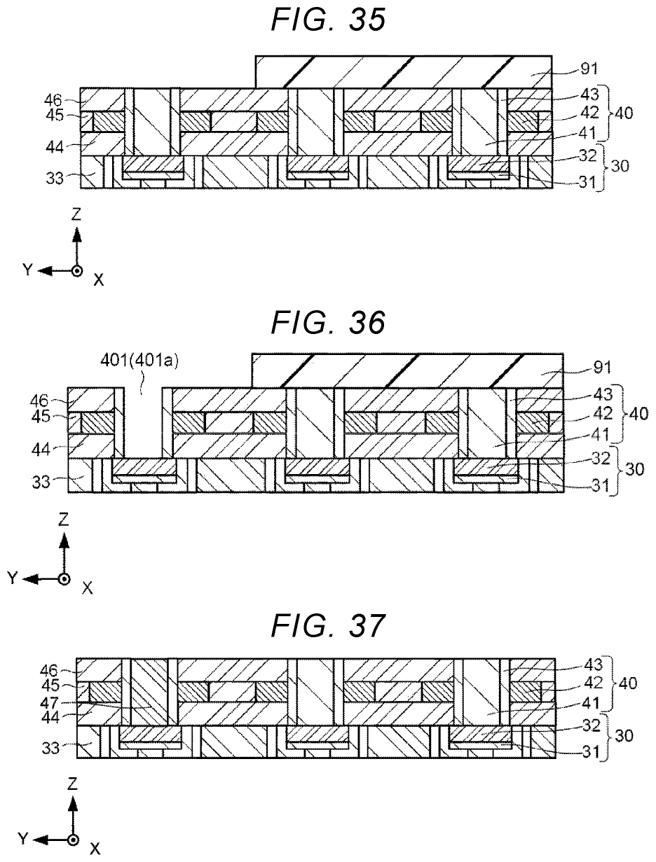

Next, as shown in FIG. 35, a mask layer 91 is formed, which covers the oxide semiconductor layer 41 disposed further inward than the end portion while the oxide semiconductor layer 41 is exposed at the end portion. The mask layer 91 contains, for example, a resin material such as PEP. The mask layer 91 can be formed by, for example, forming a resin film using a coating method and then partially erasing the resin film in the thickness direction by RIE to partially expose the upper surface of the oxide semiconductor layer 41 at the end portion.

Next, as shown in FIG. 36, the opening 401 (opening 401a) is formed at the end portion by erasing the oxide semiconductor layer 41 at the end portion by etching such as dry etching or wet etching using the mask layer 91. The oxide semiconductor layer 41 may be erased using, for example, dilute hydrofluoric acid (DHF) or buffered hydrofluoric acid (BHF). It is preferable that the exposed portion of the insulating layer 46 or the exposed portion of the insulating film 43 remains by etching. The mask layer 91 is erased after etching.

Next, as shown in FIG. 37, the insulating layer 47 that fills the opening 401a is formed. The insulating layer 47 can be formed by, for example, forming an insulating film on the opening 401a using CVD or ALD, and then partially erasing the insulating layer 47 in the thickness direction by RIE to expose the upper surface of the insulating layer 46. As a method for forming the other elements, it is possible to use the method of the first structural example. The above is the description of the manufacturing method example of the third structural example. First Modification Example of Third Structural Example

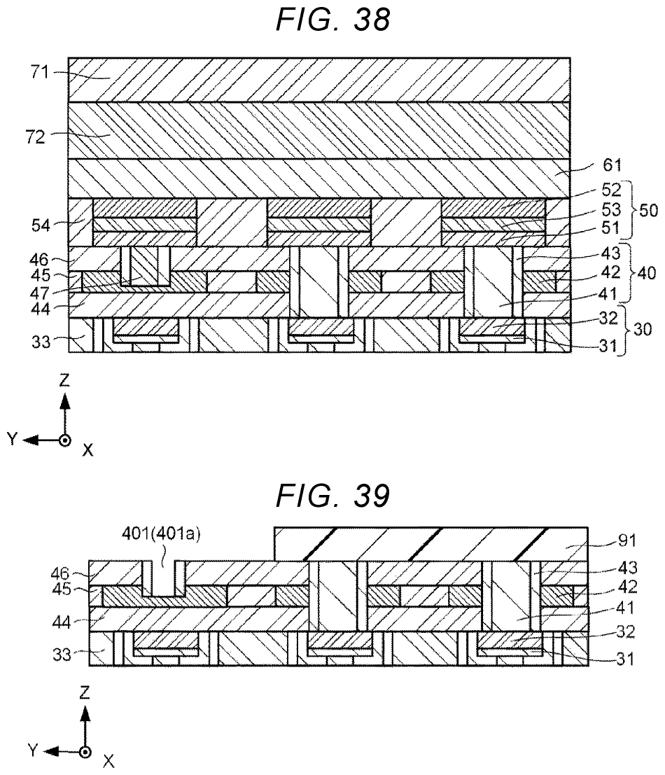

FIG. 38 is a schematic cross-sectional view showing a first modification example of the third structural example. FIG. 38 shows a part of the Y-Z cross section. As compared to the configuration shown in FIG. 33, the memory cell array shown in FIG. 38 has a configuration different from the configuration shown in FIG. 33 in that the insulating layer 47 is provided without penetrating the conductive layer 42. Hereinafter, portions different from those in FIG. 33 will be described, and other portions can be appropriately referred to in the description of FIG. 33.

The insulating layer 47 is in contact with the conductive layer 42. Therefore, the lower surface of the insulating film 43 in contact with the insulating layer 47 is also in contact with the conductive layer 42. In the X-Y plane, the diameter of the insulating layer 47 may be smaller than the diameter of the oxide semiconductor layer 41.

Even in the first modification example of the third structural example, the reliability of the semiconductor device can be prevented from being decreased by forming the dummy cell DC instead of the memory cell MC at the end portion of the memory cell array.

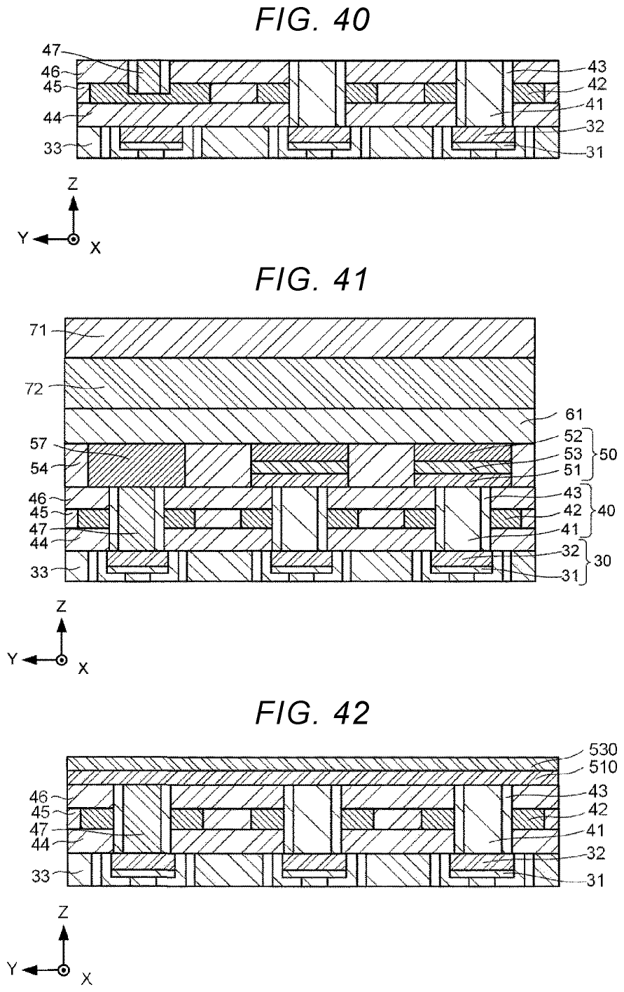

Next, a manufacturing method example of a first modification example of the third structural example of the memory cell array will be described with reference to FIGS. 39 and 40. FIGS. 39 and 40 are schematic cross-sectional views showing a manufacturing method example of a first modification example of the third structural example. FIGS. 39 and 40 show a part of the Y-Z cross section.

The insulating layer 44, the conductive layer 42, and the insulating layer 45 are formed in this order on the conductive oxide layer 32 by the same method as the above-described manufacturing method example of the third structural example, and then the opening 401 penetrating the stack of the insulating layer 44, the conductive layer 42, and the insulating layer 45 in the Z-axis direction is formed to partially expose the upper surface of the conductive oxide layer 32, and the insulating film 43 and the oxide semiconductor layer 41 are formed in the opening 401 in this order.

At this time, the opening 401 may be formed at the end portion of the memory cell array without penetrating the conductive layer 42. This is because the diameter of the opening 401a is smaller than the diameter of the inner opening 401 at the end portion.

Next, the mask layer 91 is formed, which covers the oxide semiconductor layer 41 disposed further inward than the end portion while the oxide semiconductor layer 41 of the end portion is exposed. The description of the mask layer 91 can be appropriately referred to as the description of the mask layer 91.

Next, as shown in FIG. 39, the opening 401 (opening 401a) is formed at the end portion by erasing the oxide semiconductor layer 41 at the end portion by etching such as dry etching or wet etching using the mask layer 91. It is preferable that the exposed portion of the insulating layer 46, the exposed portion of the insulating film 43, and the exposed portion of the conductive layer 42 remain by etching. The mask layer 91 is erased after etching.

Next, as shown in FIG. 40, the insulating layer 47 that fills the opening 401a is formed. The insulating layer 47 can be formed by, for example, forming an insulating film on the opening 401a using CVD or ALD, and then partially erasing the insulating layer 47 in the thickness direction by RIE to expose the upper surface of the insulating layer 46. As a method for forming the other elements, it is possible to use the method of the first structural example. The manufacturing method example of the first modification example of the third structural example is as described above.

### Second Modification Example of Third Structural Example

FIG. 41 is a schematic cross-sectional view showing a second modification example of the third structural example. FIG. 41 shows a part of the Y-Z cross section. A memory cell array shown in FIG. 41 has a configuration in which a conductor 57 is provided instead of the conductor 50 on the insulating layer 47, as compared with the configuration shown in FIG. 33. Hereinafter, portions different from those in FIG. 33 will be described, and other portions can be appropriately referred to in the description of FIG. 33.

The conductor 57 is provided on the insulating layer 47 and below the conductive layer 61. The conductor 57 is in contact with each of the insulating layer 47 and the conductive layer 61. The conductor 57 contains, for example, copper or tungsten.

Even in the second modification example of the third structural example, the reliability of the semiconductor device can be prevented from being decreased by forming the dummy cell DC instead of the memory cell MC at the end portion of the memory cell array.

Next, a manufacturing method example of a second modification example of the third structural example of the memory cell array will be described with reference to FIG. 42 to FIG. 47. FIGS. 42 to 47 are schematic cross-sectional views showing a manufacturing method example of a second modification example of the third structural example. FIGS. 42 to 47 show a part of the Y-Z cross section.

The insulating layer 44, the conductive layer 42, and the insulating layer 45 are formed in this order on the conductive oxide layer 32 by the same method as the above-described manufacturing method example of the third structural example, and then the opening 401 penetrating the stack of the insulating layer 44, the conductive layer 42, and the insulating layer 45 in the Z-axis direction is formed to partially expose the upper surface of the conductive oxide layer 32, and the insulating film 43 and the oxide semiconductor layer 41 are formed in the opening 401 in this order.

Next, as shown in FIG. 42, the conductive film 510 for forming the conductive oxide layer 51 and the conductive film 530 for forming the conductive layer 53 are formed on the oxide semiconductor layer 41 and on the insulating layer 46. The conductive film 510 and the conductive film 530 can be formed by using, for example, sputtering or ALD.

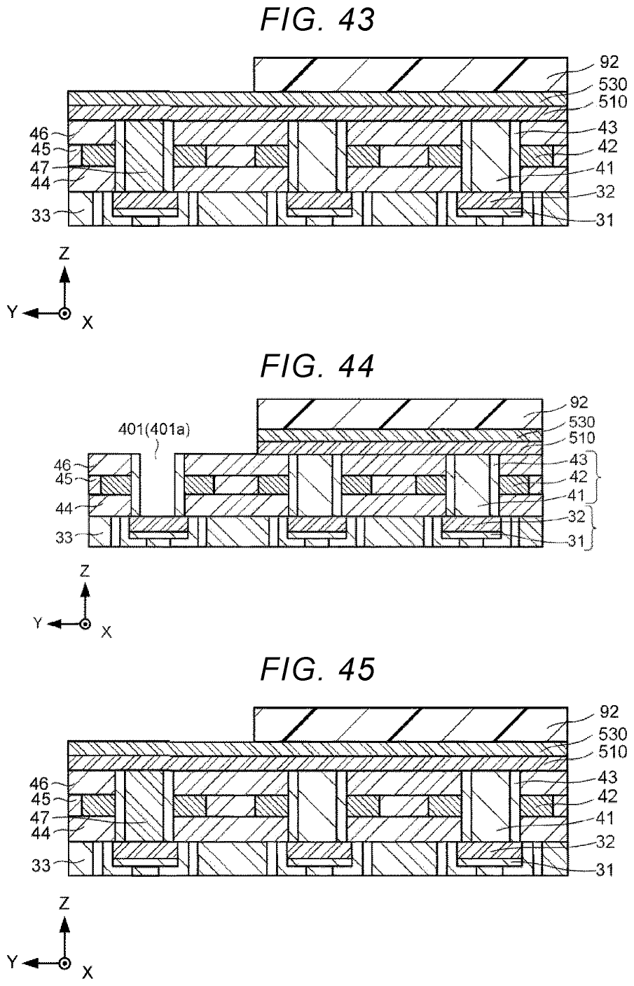

Next, as shown in FIG. 43, a mask layer 92 is formed, which covers a portion disposed further inward than the end portion while a portion is exposed, of which the conductive film 510 and the conductive film 530 overlap the oxide semiconductor layer 41 at the end portion. The mask layer 92 contains, for example, a resin material such as PEP. The mask layer 92 can be formed by, for example, forming a resin film using a coating method, and then partially erasing the resin film in the thickness direction by RIE to partially expose the upper surface of the end portion of the conductive film 530.

Next, as shown in FIG. 44, the opening 401 (opening 401a) is formed at the end portion by erasing the exposed portion of the conductive film 510 and the conductive film 530 and the oxide semiconductor layer 41 at the end portion by etching such as dry etching or wet etching using the mask layer 92. The mask layer 92 is erased after etching.

Next, as shown in FIG. 45, the insulating layer 47 that fills the opening 401a is formed. The insulating layer 47 can be formed by, for example, forming an insulating film for forming the insulating layer 47 in the opening 401a using CVD or ALD, and then partially erasing the insulating film in the thickness direction by RIE to expose the upper surface of the insulating layer 46.

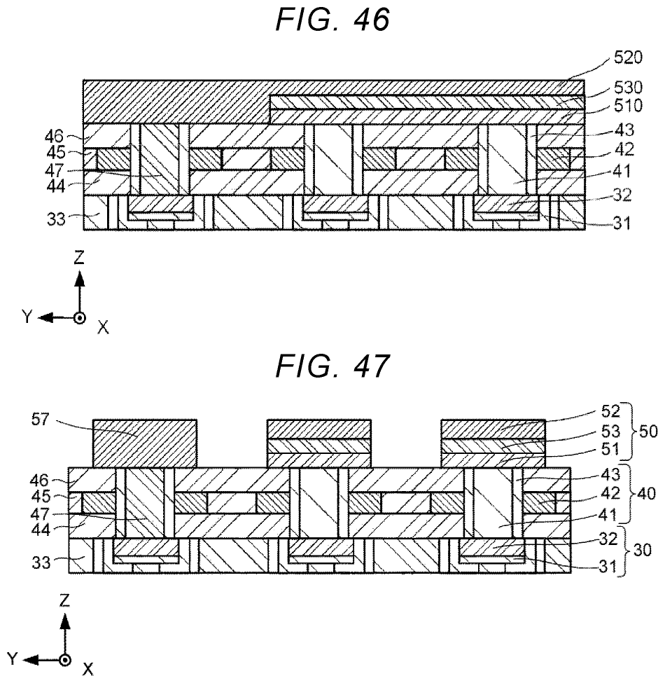

Next, as shown in FIG. 46, the conductive film 520 for forming the conductive layer 52 and the conductor 57 on the insulating layer 47, on the exposed portion of the insulating layer 46, and on the conductive film 530, is formed. The conductive film 520 can be formed by, for example, sputtering or ALD.

Next, as shown in FIG. 47, the conductive film 510, the conductive film 530, and the conductive film 520 are partially erased to form the conductor 50 and the conductor 57. The conductive film 510, the conductive film 530, and the conductive film 520 can be partially erased by etching using, for example, a resist mask. Thereafter, other elements are formed by the same method as that in the first structural example. The above is a manufacturing method example of a second modification example of the third structural example.

### Third Modification Example of Third Structural Example

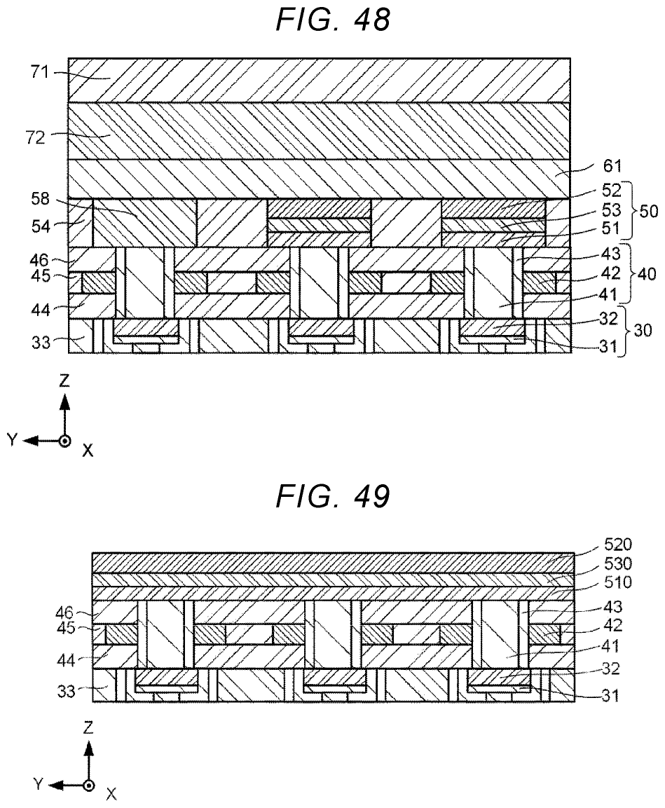

FIG. 48 is a schematic cross-sectional view showing a third modification example of the third structural example. FIG. 48 shows a part of the Y-Z cross section. As compared to the configuration shown in FIG. 33, the memory cell array shown in FIG. 48 has a configuration different from the configuration shown in FIG. 33 in that an insulating layer 58 is provided instead of the conductor 50 on the oxide semiconductor layer 41 at the end portion. Hereinafter, portions different from those in FIG. 33 will be described, and other portions can be appropriately referred to in the description of FIG. 33.

The insulating layer 58 is provided on the oxide semiconductor layer 41 and below the conductive layer 61 at the end portion. The insulating layer 58 is in contact with each of the oxide semiconductor layer 41 and the conductive layer 61. The insulating layer 58 contains, for example, silicon and oxygen.

Even in the third modification example of the third structural example, the reliability of the semiconductor device can be prevented from being decreased by forming the dummy cell DC instead of the memory cell MC at the end portion of the memory cell array.

Next, a manufacturing method example of a third modification example of the third structural example of the memory cell array will be described with reference to FIG. 49 to FIG. 54. FIGS. 49 to 54 are schematic cross-sectional views showing a manufacturing method example of a third modification example of the third structural example. FIGS. 49 to 54 show a part of the Y-Z cross section.

The insulating layer 44, the conductive layer 42, and the insulating layer 45 are formed in this order on the conductive oxide layer 32 by the same method as the above-described manufacturing method example of the third structural example, and then the opening 401 penetrating the stack of the insulating layer 44, the conductive layer 42, and the insulating layer 45 in the Z-axis direction is formed to partially expose the upper surface of the conductive oxide layer 32, and the insulating film 43 and the oxide semiconductor layer 41 are formed in the opening 401 in this order.

Next, as shown in FIG. 49, the conductive film 510 for forming the conductive oxide layer 51, the conductive film 530 for forming the conductive layer 53, and the conductive film 520 for forming the conductive layer 52 are formed on the oxide semiconductor layer 41 and on the insulating layer 46. The conductive film 510, the conductive film 520, and the conductive film 530 can be formed by using, for example, sputtering or ALD.

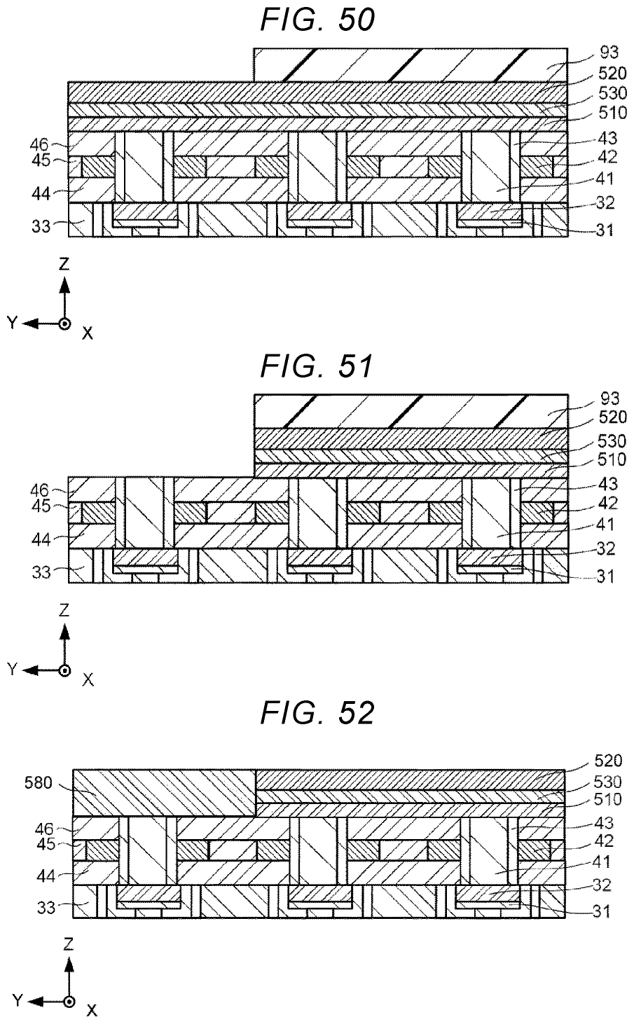

Next, as shown in FIG. 50, a mask layer 93 is formed, which covers a portion disposed further inward than the end portion while a portion is exposed, of which the conductive film 510, the conductive film 520, and the conductive film 530 overlap the oxide semiconductor layer 41 at the end portion. The mask layer 93 contains, for example, a resin material such as PEP. The mask layer 93 can be formed by, for example, forming a resin film using a coating method and then partially erasing the resin film in the thickness direction by RIE to partially expose the upper surface of the end portion of the conductive film 530.

Next, as shown in FIG. 51, the exposed portions of the conductive film 510, the conductive film 520, and the conductive film 530 are erased by etching such as dry etching or wet etching using the mask layer 93, and the upper surface of the oxide semiconductor layer 41 at the end portion is exposed. The mask layer 93 is erased after etching.

Next, as shown in FIG. 52, an insulating film 580 for forming the insulating layer 58 is formed on the oxide semiconductor layer 41 at the end portion. The insulating film 580 can be formed using, for example, CVD or ALD, and is partially erased by RIE to expose the upper surface of the conductive film 520.

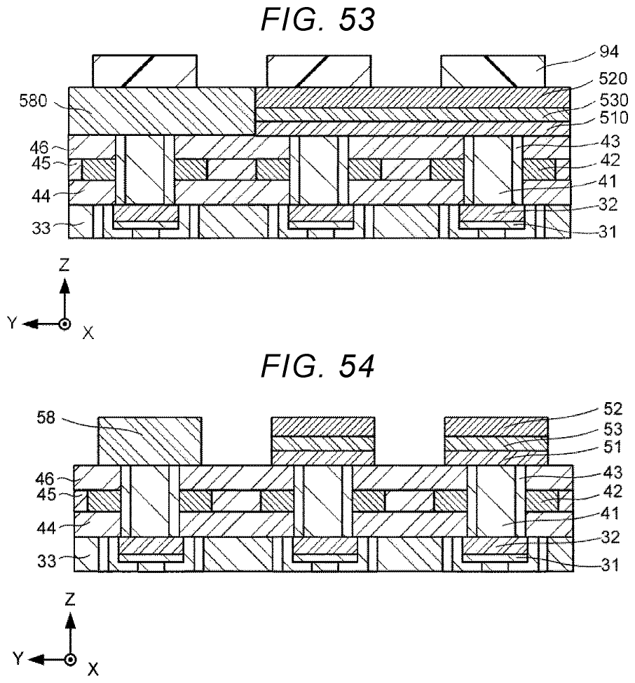

Next, as shown in FIG. 53, the mask layer 94 is formed on a part of the insulating film 580 and on a part of the conductive film 520. The mask layer 94 contains, for example, a resin material such as PEP. The mask layer 94 can be formed by, for example, forming a resin film using a coating method and then partially erasing the resin film in the thickness direction by RIE to partially expose the insulating film 580 and the conductive film 520.

Next, as shown in FIG. 54, the exposed portions of the conductive film 510, the conductive film 520, the conductive film 530, and the insulating film 580 are erased by etching such as dry etching or wet etching using the mask layer 94, and the conductive oxide layer 51, the conductive layer 52, the conductive layer 53, and the insulating layer 58 are formed. The mask layer 94 is erased after etching. Thereafter, other elements are formed by the same method as that in the first structural example. A manufacturing method example of a third modification example of the third structural example is as described above.

### Fourth Modification Example of Third Structural Example

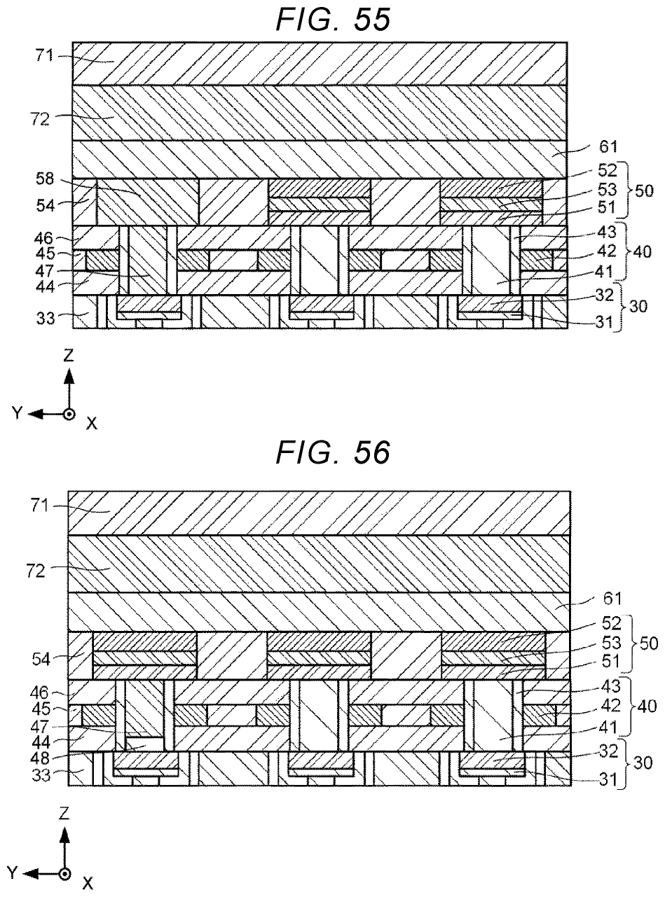

FIG. 55 is a schematic cross-sectional view showing a fourth modification example of the third structural example. FIG. 55 shows a part of the Y-Z cross section. The memory cell array shown in FIG. 55 has a configuration in which the insulating layer 58 is provided instead of the conductor 50 on the insulating layer 47, as compared with the configuration shown in FIG. 33. Hereinafter, portions different from those in FIG. 33 will be described, and other portions can be appropriately referred to in the description of FIG. 33.

The insulating layer 58 is provided on the insulating layer 47 and below the conductive layer 61. The insulating layer 58 is in contact with each of the insulating layer 47 and the conductive layer 61. For other descriptions of the insulating layer 47, the description of FIG. 33 can be appropriately referred to. For the other description of the insulating layer 58, the description of FIG. 48 can be appropriately referred to.

Even in the fourth modification example of the third structural example, the reliability of the semiconductor device can be prevented from being decreased by forming the dummy cell DC instead of the memory cell MC at the end portion of the memory cell array.

### Fifth Modification Example of Third Structural Example

FIG. 56 is a schematic cross-sectional view showing a fifth modification example of the third structural example. FIG. 56 shows a part of the Y-Z cross section. As compared to the configuration shown in FIG. 33, the memory cell array shown in FIG. 56 has a configuration different from the configuration shown in FIG. 33 in that the insulating layer 47 and the oxide semiconductor layer 48 are stacked instead of the oxide semiconductor layer 1 at the end portion. Hereinafter, portions different from those in FIG. 33 will be described, and other portions can be appropriately referred to in the description of FIG. 33.

The insulating layer 47 is provided separately from the conductive oxide layer 32 and is provided in contact with the conductive oxide layer 51. Other descriptions of the insulating layer 47 can be appropriately referred to from the description of FIG. 33.

The oxide semiconductor layer 48 is provided between the conductive oxide layer 32 and the insulating layer 47. The oxide semiconductor layer 48 is in contact with the conductive oxide layer 32 and the insulating layer 47. The oxide semiconductor layer 48 can be formed by partially erasing the oxide semiconductor layer 41 at the end portion as in FIG. 36. The insulating layer 47 can be formed by forming an insulating film to fill the opening 401a as in FIG. 37.

Even in the fifth modification example of the third structural example, the reliability of the semiconductor device can be prevented from being decreased by forming the dummy cell DC instead of the memory cell MC at the end portion of the memory cell array.

### Sixth Modification Example of Third Structural Example

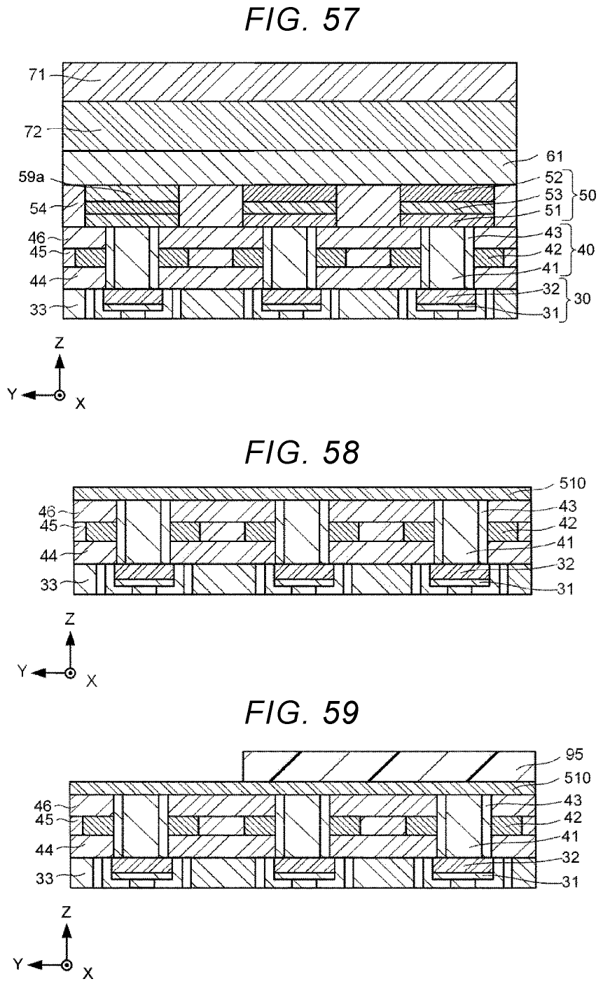

FIG. 57 is a schematic cross-sectional view showing a sixth modification example of the third structural example. FIG. 57 shows a part of the Y-Z cross section. As compared to the configuration shown in FIG. 33, the memory cell array shown in FIG. 57 has a configuration different from that shown in FIG. 33 in that the conductive oxide layer 51 is not provided and the insulating layer 59a is provided at the end portion. Hereinafter, portions different from those in FIG. 33 will be described, and other portions can be appropriately referred to in the description of FIG. 33.

The conductive layer 53 of the end portion is provided in contact above the oxide semiconductor layer 41.

The insulating layer 59a is provided on the conductive layer 52 and is provided below the conductive layer 61. The insulating layer 59a is provided in contact with the conductive layer 52 and the conductive layer 61. The insulating layer 59a contains, for example, silicon and oxygen.

Even in the sixth modification example of the third structural example, the reliability of the semiconductor device can be prevented from being decreased by forming the dummy cell DC instead of the memory cell MC at the end portion of the memory cell array. For example, the insulating layer 59a can reduce a short circuit between the conductive layer 61 and the oxide semiconductor layer 41 or the conductive layer 42.

Next, a manufacturing method example of a sixth modification example of the third structural example of the memory cell array will be described with reference to FIG. 58 to FIG. 63. FIGS. 58 to 63 are schematic cross-sectional views showing a manufacturing method example of a sixth modification example of the third structural example. FIGS. 58 to 63 show a part of the Y-Z cross section.

The insulating layer 44, the conductive layer 42, and the insulating layer 45 are formed in this order on the conductive oxide layer 32 by the same method as the above-described manufacturing method example of the third structural example, and then the opening 401 penetrating the stack of the insulating layer 44, the conductive layer 42, and the insulating layer 45 in the Z-axis direction is formed to partially expose the upper surface of the conductive oxide layer 32, and the insulating film 43 and the oxide semiconductor layer 41 are formed in the opening 401 in this order.

Next, as shown in FIG. 58, the conductive film 510 for forming the conductive oxide layer 51 is formed on the oxide semiconductor layer 41 and on the insulating layer 46. The conductive film 510 can be formed by using, for example, sputtering or ALD.

Next, as shown in FIG. 59, a mask layer 95 is formed, which covers that portion of the conductive film 510 that is disposed further inward than the end portion while a portion is exposed, of which the conductive film 510 overlaps the oxide semiconductor layer 41 at the end portion. The mask layer 95 contains, for example, a resin material such as PEP. The mask layer 95 can be formed by, for example, forming a resin film using a coating method and then partially erasing the resin film in the thickness direction by RIE to partially expose the upper surface of the end portion of the conductive film 510.

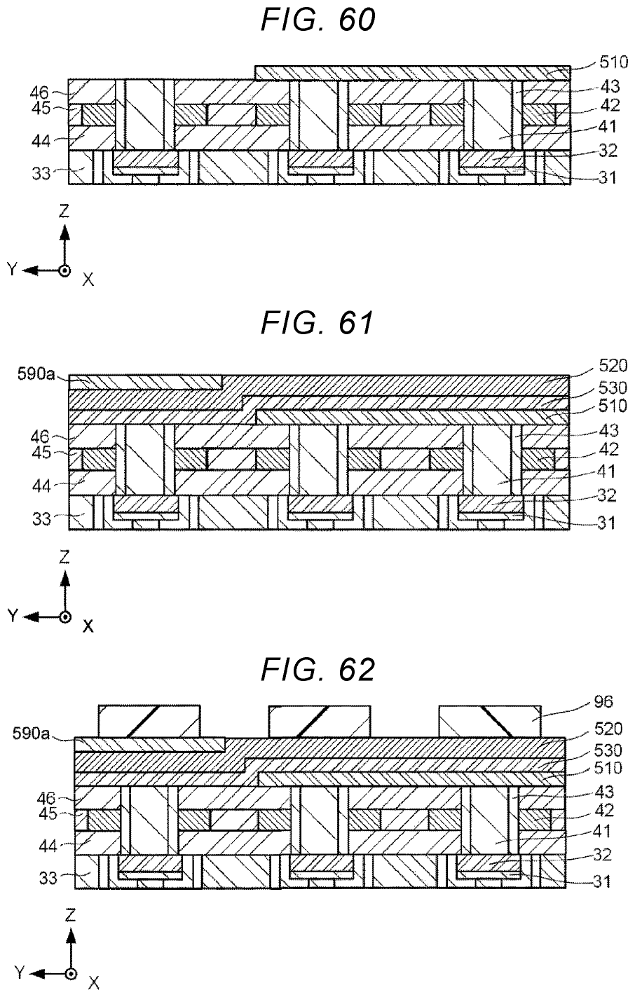

Next, as shown in FIG. 60, the exposed portion of the conductive film 510 is erased by etching such as dry etching or wet etching using the mask layer 95, and the upper surface of the oxide semiconductor layer 41 at the end portion is exposed. The mask layer 95 is erased after etching.

Next, as shown in FIG. 61, the conductive film 530 for forming the conductive layer 53 and the conductive film 520 for forming the conductive layer 52 are formed on the oxide semiconductor layer 41, on the insulating layer 46, and on the conductive film 510 at the end portion. The conductive film 520 and the conductive film 530 can be formed by using, for example, sputtering or ALD. Thereafter, the insulating film 590a for forming the insulating layer 59a on the portion of the conductive film 520 overlapping the oxide semiconductor layer 41 at the end portion is formed. The insulating film 590a can be formed using, for example, CVD or ALD, and is partially erased by RIE to expose the upper surface of the conductive film 520.

Next, as shown in FIG. 62, the mask layer 96 is formed on a part of the insulating film 590a and on a part of the conductive film 520. The mask layer 96 contains, for example, a resin material such as PEP. The mask layer 96 can be formed by, for example, forming a resin film using a coating method and then partially erasing the resin film in the thickness direction by RIE to partially expose the insulating film 590a and the conductive film 520.

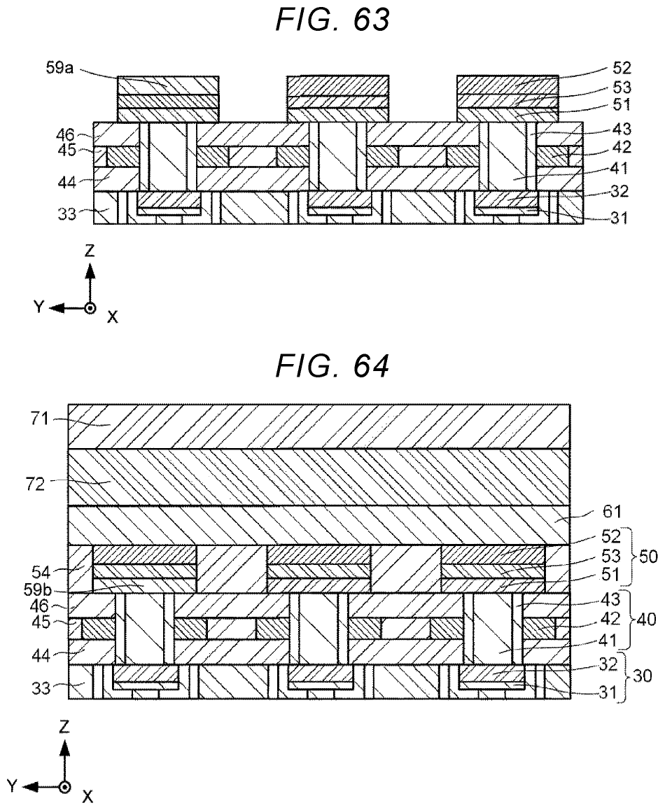

Next, as shown in FIG. 63, the exposed portions of the conductive film 510, the conductive film 520, the conductive film 530, and the insulating film 590a are erased by etching such as dry etching or wet etching using the mask layer 96, and the conductor 50 and the insulating layer 59a are formed. The mask layer 96 is erased after etching. Thereafter, other elements are formed by the same method as that in the first structural example. A manufacturing method example of a sixth modification example of the third structural example is as described above.

### Seventh Modification Example of Third Structural Example

FIG. 64 is a schematic cross-sectional view showing a seventh modification example of the third structural example. FIG. 64 shows a part of the Y-Z cross section. As compared to the configuration shown in FIG. 33, the memory cell array shown in FIG. 64 has a configuration different from the configuration shown in FIG. 33 in that the insulating layer 59b is provided instead of the conductive oxide layer 51 at the end portion. Hereinafter, portions different from those in FIG. 33 will be described, and other portions can be appropriately referred to in the description of FIG. 33.

The conductive layer 53 of the end portion is provided in contact above the insulating layer 59b.

The insulating layer 59b is provided on the oxide semiconductor layer 41 at the end portion and is provided below the conductive layer 53. The insulating layer 59b is provided in contact with the oxide semiconductor layer 41 and the conductive layer 53. The insulating layer 59b contains, for example, silicon and oxygen.

Even in the seventh modification example of the third structural example, the reliability of the semiconductor device can be prevented from being decreased by forming the dummy cell DC instead of the memory cell MC at the end portion of the memory cell array. For example, the insulating layer 59b can reduce a short circuit between the conductive layer 61 and the oxide semiconductor layer 41 or the conductive layer 42.

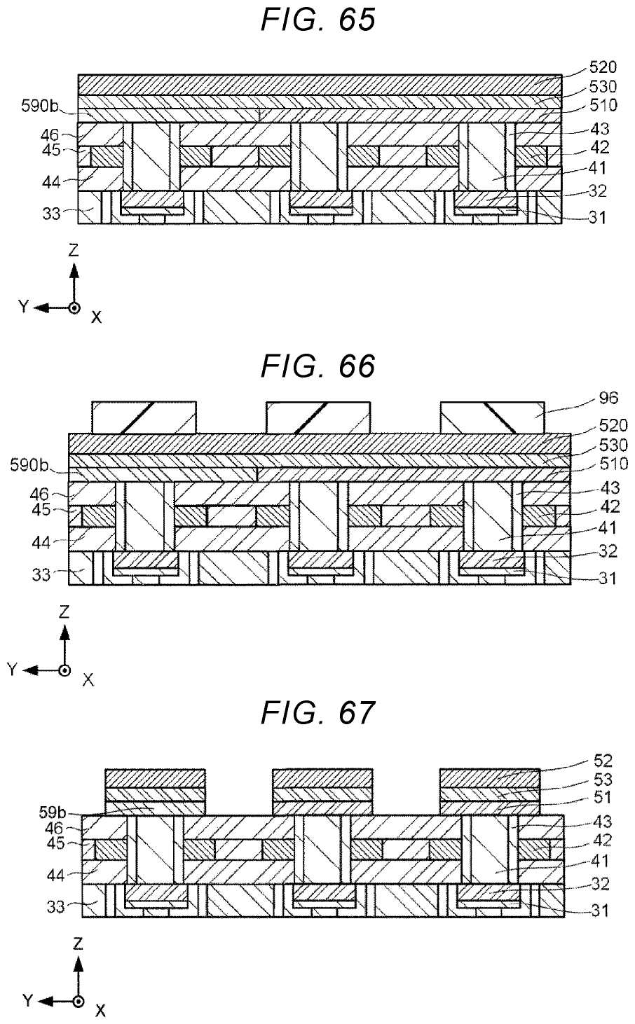

Next, a manufacturing method example of a seventh modification example of the third structural example of the memory cell array will be described with reference to FIG. 65 to FIG. 67. FIGS. 65 to 67 are schematic cross-sectional views showing a manufacturing method example of a seventh modification example of the third structural example. FIGS. 65 to 67 show a part of the X-Z cross section.

The insulating layer 44, the conductive layer 42, and the insulating layer 45 are formed in this order on the conductive oxide layer 32 by the same method as the above-described manufacturing method example of the third structural example, and then the opening 401 penetrating the stack of the insulating layer 44, the conductive layer 42, and the insulating layer 45 in the Z-axis direction is formed to partially expose the upper surface of the conductive oxide layer 32, and the insulating film 43 and the oxide semiconductor layer 41 are formed in the opening 401 in this order.

Next, the conductive film 510 is partially erased by the same method as that in FIGS. 58 to 60, and the upper surface of the oxide semiconductor layer 41 at the end portion is exposed.

Next, as shown in FIG. 65, an insulating film 590b for forming the insulating layer 59b on the exposed portion of the oxide semiconductor layer 41 and the insulating layer 46 at the end portion is formed. The insulating film 590b can be formed using, for example, CVD or ALD, and is partially erased by RIE to expose the upper surface of the conductive film 510. Thereafter, the conductive film 530 for forming the conductive layer 53 and the conductive film 520 for forming the conductive layer 52 are formed on the insulating film 590b and on the conductive film 510. The conductive film 520 and the conductive film 530 can be formed by using, for example, sputtering or ALD.

Next, as shown in FIG. 66, the mask layer 96 is formed on a part of the conductive film 520. The mask layer 96 contains, for example, a resin material such as PEP. The mask layer 96 can be formed by, for example, forming a resin film using a coating method and then partially erasing the resin film in the thickness direction by RIE to partially expose the conductive film 520.

Next, as shown in FIG. 67, the exposed portions of the conductive film 510, the conductive film 520, the conductive film 530, and the insulating film 590b are erased by etching such as dry etching or wet etching using the mask layer 96, and the conductor 50 and the insulating layer 59b are formed. The mask layer 96 is erased after etching. Thereafter, other elements are formed by the same method as that in the first structural example. A manufacturing method example of a seventh modification example of the third structural example is as described above.

### Eighth Modification Example of Third Structural Example

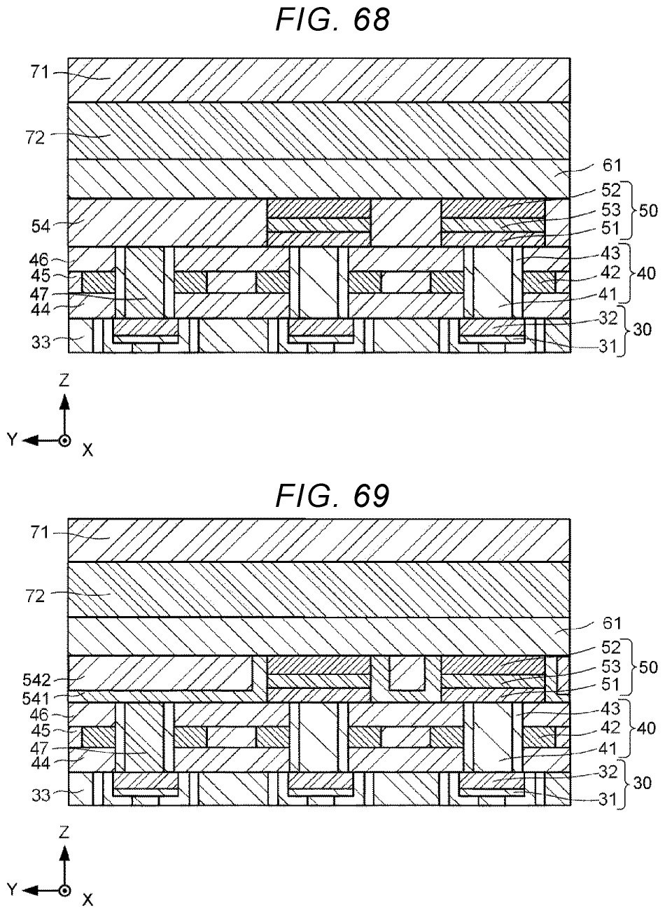

FIG. 68 is a schematic cross-sectional view showing an eighth modification example of the third structural example. FIG. 68 shows a part of the Y-Z cross section. As compared to the configuration shown in FIG. 33, the memory cell array shown in FIG. 68 has a configuration different from the configuration shown in FIG. 33 in that the conductor 50 is not provided on the insulating layer 47. The insulating layer 47 is in contact with the insulating layer 54. The configuration in which the conductor 50 is not provided on the insulating layer 47 can be formed by erasing the portion of the stacked film of the conductive film 510, the conductive film 530, and the conductive film 520, which overlaps the insulating layer 47 at the end portion, and then forming the conductive layer 61 or the insulating layer 54, in the same manner as that in FIGS. 49 to 51. For other portions, the description in FIG. 33 can be appropriately referred to.

Even in the eighth modification example of the third structural example, the reliability of the semiconductor device can be prevented from being decreased by forming the dummy cell DC instead of the memory cell MC at the end portion of the memory cell array. For example, the insulating layer 47 and the insulating layer 54 can reduce the short circuit between the conductive layer 61 and the conductive layer 42.

### Ninth Modification Example of Third Structural Example

FIG. 69 is a schematic cross-sectional view showing a ninth modification example of the third structural example. FIG. 69 shows a part of the Y-Z cross section. The memory cell array shown in FIG. 69 has a configuration in which an insulating layer 541 and an insulating layer 542 are provided instead of the insulating layer 54, as compared with the configuration shown in FIG. 68. Hereinafter, portions different from those in FIG. 68 will be described, and other portions can be appropriately referred to in the description of FIG. 68.

The insulating layer 541 is provided on the oxide semiconductor layer 41 at the end portion and is in contact with the side surface of the conductor 50. The insulating layer 541 contains, for example, silicon and oxygen.

The insulating layer 542 is provided on the insulating layer 541 and is provided below the conductive layer 61. The insulating layer 542 contains, for example, silicon and oxygen.

Even in the ninth modification example of the third structural example, the reliability of the semiconductor device can be prevented from being decreased by forming the dummy cell DC instead of the memory cell MC at the end portion of the memory cell array. For example, the insulating layer 47, the insulating layer 541, and the insulating layer 542 can reduce the short circuit between the conductive layer 61 and the conductive layer 42.

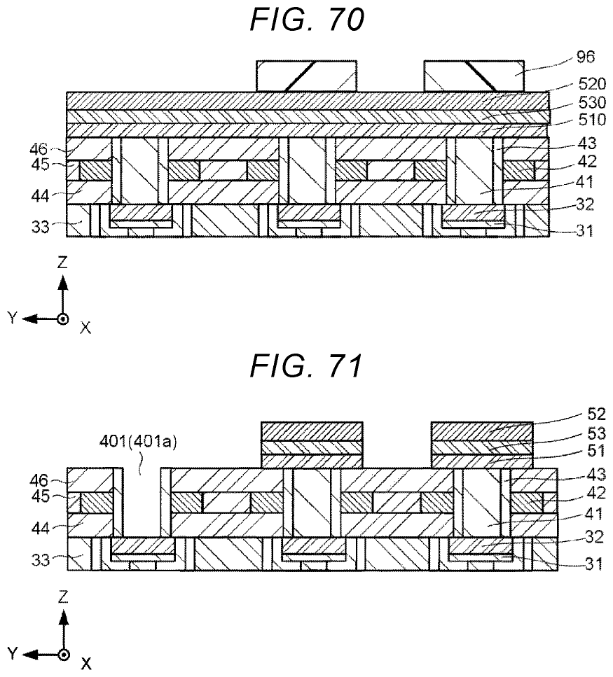

Next, a manufacturing method example of a ninth modification example of the third structural example of the memory cell array will be described with reference to FIG. 70 to FIG. 73. FIGS. 70 to 73 are schematic cross-sectional views showing a manufacturing method example of a ninth modification example of the third structural example. FIGS. 70 to 73 show a part of the Y-Z cross section.

The insulating layer 44, the conductive layer 42, and the insulating layer 45 are formed in this order on the conductive oxide layer 32 by the same method as the above-described manufacturing method example of the third structural example, and then the opening 401 penetrating the stack of the insulating layer 44, the conductive layer 42, and the insulating layer 45 in the Z-axis direction is formed to partially expose the upper surface of the conductive oxide layer 32, and the insulating film 43 and the oxide semiconductor layer 41 are formed in the opening 401 in this order.

Next, as shown in FIG. 70, the conductive film 510, the conductive film 530, and the conductive film 520 are stacked by the same method as that in FIGS. 65 and 66, the mask layer 96 is partially formed on a part of the stack, and the upper surface of the portion of the conductive film 520 overlapping the oxide semiconductor layer 41 at the end portion is exposed.

Next, as shown in FIG. 71, the exposed portions of the conductive film 510, the conductive film 520, the conductive film 530, and the oxide semiconductor layer 41 are erased by etching such as dry etching or wet etching using the mask layer 96, and the conductor 50 and the opening 401a are formed. The mask layer 96 is erased after etching.

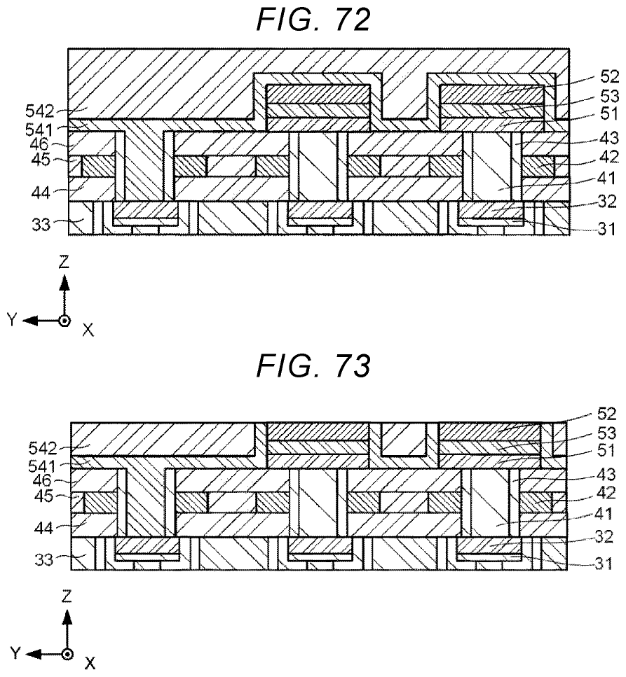

Next, as shown in FIG. 72, the insulating layer 541 covers the conductor 50 and fills the opening 401a, and the insulating layer 542 is formed on the insulating layer 541. The insulating layer 541 and the insulating layer 542 can be formed by forming an insulating film using, for example, CVD or ALD.

Next, as shown in FIG. 73, the insulating layer 541 and the insulating layer 542 are partially erased in the thickness direction by RIE to expose the upper surface of the conductive layer 52. Thereafter, other elements are formed by the same method as that in the first structural example. A manufacturing method example of a ninth modification example of the third structural example is as described above.

### Tenth Modification Example of Third Structural Example

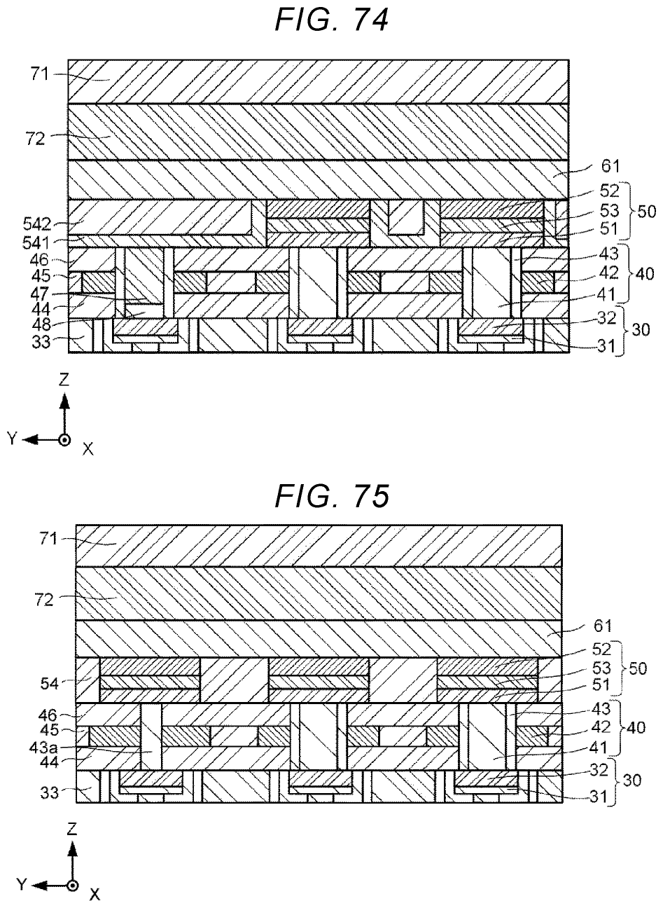

FIG. 74 is a schematic cross-sectional view showing a tenth modification example of the third structural example. FIG. 74 shows a part of the Y-Z cross section. As compared to the configuration shown in FIG. 33, the memory cell array shown in FIG. 74 has a configuration unlike the configuration shown in FIG. 33 in that the insulating layer 47 and the oxide semiconductor layer 48 are stacked instead of the oxide semiconductor layer 41 at the end portion, and as compared to the configuration shown in FIG. 68, has a configuration different from the configuration shown in FIG. 68 in that the insulating layer 541 and the insulating layer 542 are provided instead of the insulating layer 54. The insulating layer 541 is provided on the insulating layer 47. The description of the stack of the insulating layer 47 and the oxide semiconductor layer 48 can be appropriately referred to from the description of FIG. 56. Other descriptions of the insulating layer 541 and the insulating layer 542 can be appropriately referred to from the description of FIG. 68. For other portions, the description in FIG. 33 can be appropriately referred to.

Even in the tenth modification example of the third structural example, the reliability of the semiconductor device can be prevented from being decreased by forming the dummy cell DC instead of the memory cell MC at the end portion of the memory cell array. For example, the insulating layer 47, the insulating layer 541, and the insulating layer 542 can reduce the short circuit between the conductive layer 61 and the conductive layer 42.

### Eleventh Modification Example of Third Structural Example

FIG. 75 is a schematic cross-sectional view showing an eleventh modification example of the third structural example. FIG. 75 shows a part of the Y-Z cross section. A memory cell array shown in FIG. 75 has a configuration having an insulating film 43a instead of the insulating layer 47, as compared with the configuration shown in FIG. 33. Hereinafter, portions different from those in FIG. 33 will be described, and other portions can be appropriately referred to in the description of FIG. 33.

The insulating film 43a is formed in the same layer as that of the insulating film 43. The insulating film 43a can be formed, for example, by filling the opening 401a with the insulating film 43 when the diameter of the opening 401a is smaller than the diameter of the opening 401 inside the opening 401a.

Even in the eleventh modification example of the third structural example, the reliability of the semiconductor device can be prevented from being decreased by forming the dummy cell DC instead of the memory cell MC at the end portion of the memory cell array. For example, the insulating film 43 at the end portion can reduce a short circuit between the conductive layer 61 and the conductive layer 42.

It is possible to appropriately combine the first structural example, the second structural example, and the third structural example. For example, the conductors 50c, 50c, and 50d in the second structural example may be formed on the dummy cell DC in the third structural example. In addition, any of the conductor 50c, the conductor 50c, and the conductor 50d in the second structural example may be used as the insulating layer 58.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device comprising:
a first oxide semiconductor layer extending in a first direction;
a first wiring extending in a second direction, the second direction intersecting the first direction, and the first wiring surrounding the first oxide semiconductor layer;
a first insulating film disposed between the first wiring and the first oxide semiconductor layer;
a first conductor disposed on the first oxide semiconductor layer;
a second wiring disposed on the first conductor and extending in a third direction, the third direction intersecting each of the first direction and the second direction;
a first insulating layer in contact with a side surface of the second wiring; and
a second insulating layer disposed on the first insulating layer and having oxygen permeability lower than oxygen permeability of the first insulating layer.

2. The semiconductor device according to claim 1, further comprising:
a second oxide semiconductor layer extending in the first direction;
a third wiring extending in the second direction and surrounding the second oxide semiconductor layer;
a second insulating film disposed between the third wiring and the second oxide semiconductor layer;
a second conductor disposed on the second oxide semiconductor layer; and
a fourth wiring disposed on the second conductor and extending in the third direction, wherein
each of the first conductor and the second conductor extends in a fourth direction, the fourth direction intersecting each of the second direction and the third direction, in a plane including the second direction and the third direction, and
a length of the second conductor in the fourth direction is longer than a length of the first conductor in the fourth direction.

3. The semiconductor device according to claim 1, further comprising:
a first layer extending in the first direction;
a fifth wiring extending in the second direction and surrounding the first layer;
a second layer disposed on the first layer; and
a third layer disposed on the second layer and disposed below the second wiring, wherein
at least one selected from the group consisting of the first layer, the second layer, and the third layer is an insulating layer.

4. The semiconductor device according to claim 1, further comprising:
a barrier film disposed on the second insulating layer and having hydrogen permeability lower than hydrogen permeability of the second insulating layer.

5. The semiconductor device according to claim 1, further comprising:
a capacitor disposed below the first oxide semiconductor layer.

6. The semiconductor device according to claim 3, further comprising:
a barrier film disposed on the second insulating layer and having hydrogen permeability lower than hydrogen permeability of the second insulating layer.

7. The semiconductor device according to claim 3, further comprising:
a capacitor disposed below the first oxide semiconductor layer.

8. The semiconductor device according to claim 1, wherein the first oxide semiconductor layer has a columnar body structure.

9. The semiconductor device according to claim 1, wherein the first oxide semiconductor layer includes at least one of indium, zinc or tin.

10. The semiconductor device according to claim 1, wherein the first oxide semiconductor layer has one of an amorphous structure or a crystalline structure.

11. The semiconductor device according to claim 1, wherein the first conductor includes one of tungsten or titanium nitride.

12. The semiconductor device according to claim 1, wherein the first insulating film includes silicon and oxygen or nitrogen.

13. The semiconductor device according to claim 1, wherein the first insulating layer includes silicon and oxygen or nitrogen.

14. The semiconductor device according to claim 1, wherein the second insulating layer includes silicon and oxygen or nitrogen.
